(19) United States
(12) Patent Application Publication
(10) Pub. No.: US 2025/0215125 A1
(43) Pub. Date: Jul. 3, 2025

(54) CYCLIC OLEFIN-BASED RESIN COMPOSITION, VARNISH, CROSSLINKED BODY, FILM, SHEET, CIRCUIT BOARD, ELECTRONIC APPARATUS, AND PREPREG

(71) Applicants: MITSUI CHEMICALS, INC., Chuo-ku, Tokyo (JP); PANASONIC HOLDINGS CORPORATION, Kadoma-shi, Osaka (JP)

(72) Inventors: Hirohiko MURASE, Kuga-gun, Yamaguchi (JP); Koutarou ASAHINA, Sodegaura-shi, Chiba (JP); Manami UENO, Sodegaura-shi, Chiba (JP); Fumito TAKEUCHI, Sodegaura-shi, Chiba (JP); Yuki KITAI, Osaka (JP); Ryusei KOZAWA, Osaka (JP)

(73) Assignees: MITSUI CHEMICALS, INC., Chuo-ku, Tokyo (JP); PANASONIC HOLDINGS CORPORATION, Kadoma-shi, Osaka (JP)

(21) Appl. No.: 18/851,847

(22) PCT Filed: Mar. 27, 2023
(86) PCT No.: PCT/JP2023/012273

§ 371 Date: Sep. 27, 2024

(30) Foreign Application Priority Data
Mar. 30, 2022 (JP) 2022-056329

(51) Int. Cl. C08F 210/18; C08J 5/24; C08K 5/134; C08K 5/23; C08L 23/0807; C09D 7/20; C09D 123/08

(52) U.S. Cl. CPC C08F 210/18; C08J 5/244; C08K 5/134; C08K 5/23; C08L 23/083; C09D 123/083; C08J 2323/08; C08L 2203/20; C08L 2205/025; C09D 7/20

(57) ABSTRACT

A cyclic olefin-based resin composition contains a cyclic olefin-based copolymer (A), an azo compound (B) which has an azo group in a molecule and includes no heteroatom other than a nitrogen atom constituting the azo group, and a hindered phenol compound (C), in which an iodine value of the cyclic olefin-based copolymer (A) is in a range of equal to or more than 20 g/100 g and equal to or less than 120 g/100 g, and a number-average molecular weight Mn of the cyclic olefin-based copolymer (A) is in a range of equal to or more than 3,000 and equal to or less than 30,000.

### TECHNICAL FIELD

The present invention relates to a cyclic olefin-based resin composition, a varnish, a crosslinked body, a film, a sheet, a circuit board, an electronic apparatus, and a prepreg.

### BACKGROUND ART

A cyclic olefin-based copolymer is excellent in heat resistance, mechanical properties, transparency, dielectric properties, solvent resistance, moldability, dimensional stability, and the like, and thus is used in various fields (for example, see Patent Documents 1 and 2).

In addition, in recent years, from the viewpoint that the cyclic olefin-based copolymer has an excellent balance of heat resistance and dielectric properties, for example, the cyclic olefin-based copolymer has also been studied as a material for electronic components such as a printed wiring board (for example, see Patent Documents 2 and 3).

Patent Document 2 discloses a cyclic olefin-based copolymer having a crosslinkable group. It is disclosed that a crosslinked body obtained by crosslinking the cyclic olefin-based copolymer has excellent dielectric property stability over time, and also has excellent heat resistance, transparency, mechanical properties, and the like, so that the crosslinked body is suitable for high-frequency applications such as a high-frequency circuit board.

Patent Document 3 discloses a crosslinkable resin composition consisting of a cyclic olefin-based resin, an organic peroxide, a crosslinking aid, and powdery red phosphorus. It is disclosed that a crosslinked resin molded product obtained by heating and crosslinking the crosslinkable resin composition has dielectric properties in a high-frequency band and heat resistance to solder, and also has high flame retardancy and mechanical strength, so that the crosslinked resin molded product is suitable for applications in which the dielectric properties, heat resistance, flame retardancy, and mechanical properties are required, such as a printed wiring board and a computer component.

### RELATED DOCUMENT

### Patent Document

[Patent Document 1] International Publication No. WO 2006/118261
[Patent Document 2] International Publication No. WO 2012/046443
[Patent Document 3] Japanese Unexamined Patent Publication No. 2005-47992

### SUMMARY OF THE INVENTION

### Technical Problem

In a case of obtaining a crosslinked body of the cyclic olefin-based copolymer having a crosslinkable group, there is a problem that dielectric properties of the crosslinked body are deteriorated by a polar compound, which is a decomposition residue of an initiator, remaining in the crosslinked body. In addition, in a case where the crosslinked body is exposed to a high temperature in a step prior to crosslinking during processing, there is a problem that the dielectric properties are deteriorated due to oxidation degradation of the cyclic olefin-based copolymer.

As described above, there is room for improvement in the crosslinked body formed of the cyclic olefin-based copolymer having a crosslinkable group in that, even after the crosslinking step, excellent dielectric properties of the cyclic olefin-based copolymer are maintained.

The present invention has been made in view of the above-described circumstances, and provides a cyclic olefin-based resin composition in which excellent dielectric properties of the cyclic olefin-based copolymer can be maintained even after a crosslinking step.

### Solution to Problem

The inventors of the present invention carried out intensive studies in order to achieve the above-described object. As a result, it is found that the above-described object can be achieved by using, in combination, a specific radical initiator, a hindered phenol compound, and a cyclic olefin-based copolymer having an iodine value within a specific range, thereby completing the present invention.

That is, according to the present invention, there are provided a cyclic olefin-based resin composition, a varnish, a crosslinked body, a film, a sheet, a circuit board, an electronic apparatus, and a prepreg, which are shown below.

[1]

A cyclic olefin-based resin composition containing:
a cyclic olefin-based copolymer (A);
an azo compound (B) which has an azo group in a molecule and includes no heteroatom other than a nitrogen atom constituting the azo group; and
a hindered phenol compound (C),
in which the cyclic olefin-based copolymer (A) includes a repeating unit derived from one or more olefins represented by General Formula (1), a repeating unit derived from one or more cyclic non-conjugated dienes represented by General Formula (2), and a repeating unit derived from one or more cyclic olefins represented by General Formula (3),
an iodine value of the cyclic olefin-based copolymer (A) is in a range of equal to or more than 20 g/100 g and equal to or less than 120 g/100 g, and
a number-average molecular weight Mn of the cyclic olefin-based copolymer (A) is in a range of equal to or more than 3,000 and equal to or less than 30,000,

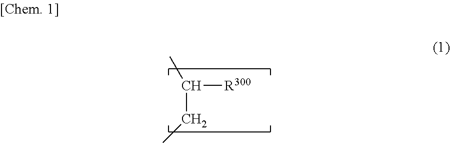

in General Formula (1), R³⁰⁰ represents a hydrogen atom or a linear or branched hydrocarbon group having 1 to 29 carbon atoms,

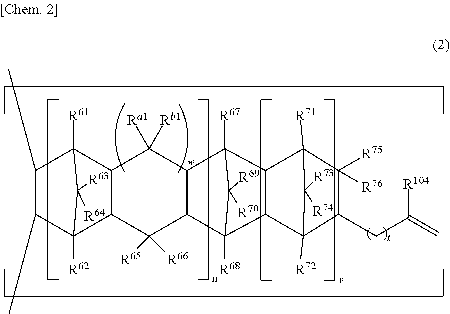

in General Formula (2), u is 0 or 1, v is 0 or a positive integer, w is 0 or 1, R⁶¹ to R⁷⁶, R^{a1}, and R^{b1} may be the same or different from each other, and are each a hydrogen atom, a halogen atom, an alkyl group having 1 to 20 carbon atoms, a halogenated alkyl group having 1 to 20 carbon atoms, a cycloalkyl group having 3 to 15 carbon atoms, or an aromatic hydrocarbon group having 6 to 20 carbon atoms, R¹⁰⁴ is a hydrogen atom or an alkyl group having 1 to 10 carbon atoms, t is a positive integer of 0 to 10, and R⁷⁵ and R⁷⁶ may be bonded to each other to form a monocyclic ring or a polycyclic ring,

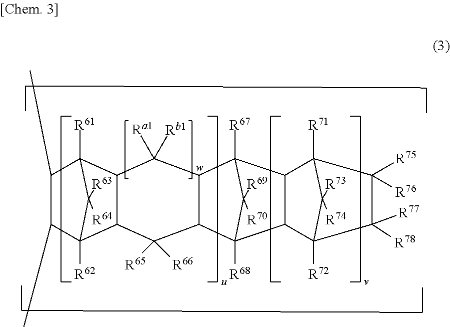

in General Formula (3), u is 0 or 1, v is 0 or a positive integer, w is 0 or 1, R⁶¹ to R⁷⁸, R^{a1}, and R^{b1} may be the same or different from each other, and are each a hydrogen atom, a halogen atom, an alkyl group having 1 to 20 carbon atoms, a halogenated alkyl group having 1 to 20 carbon atoms, a cycloalkyl group having 3 to 15 carbon atoms, or an aromatic hydrocarbon group having 6 to 20 carbon atoms, and R⁷⁵ to R⁷⁸ may be bonded to each other to form a monocyclic ring or a polycyclic ring.

[2]

The cyclic olefin-based resin composition according to [1],
in which the cyclic olefin-based copolymer (A) includes, as the repeating unit represented by General Formula (2), a repeating unit derived from 5-vinyl-2-norbornene, and includes, as the repeating unit represented by General Formula (3), at least one of a repeating unit derived from bicyclo[2.2.1]-2-heptene or a repeating unit derived from tetracyclo [4.4.0.1^{2,5}0.1^{7,10}]-3-dodecene.

[3]

The cyclic olefin-based resin composition according to [1] or [2],
in which the azo compound (B) includes a compound represented by General Formula (4),

[Chem. 4]

R²¹—N═N—R²² (4)
in General Formula (4), R²¹ and R²² each independently represent a hydrogen atom or an alkyl group.

[4]

The cyclic olefin-based resin composition according to [3],
in which, in General Formula (4), the alkyl group represented by R²¹ and R²² has 1 to 8 carbon atoms.

[5]

The cyclic olefin-based resin composition according to [4],
in which the azo compound (B) includes at least one of a compound represented by Formula (5) or a compound represented by Formula (6),

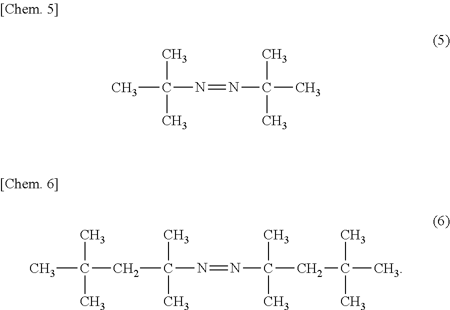

[6]

The cyclic olefin-based resin composition according to any one of [1] to [5],
in which the hindered phenol compound (C) has a structure represented by General Formula (7),

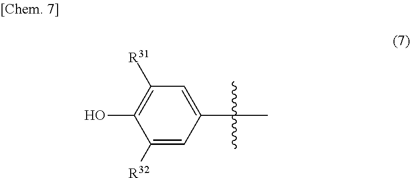

in General Formula (7), R³¹ represents an alkyl group having 1 to 4 carbon atoms, and R³² represents a hydrogen atom or an alkyl group having 1 to 4 carbon atoms.

[7]

The cyclic olefin-based resin composition according to [6],
in which a compound in which R³¹ and R³² in General Formula (7) are both a t-butyl group is included.

[8]

The cyclic olefin-based resin composition according to [7],
in which the hindered phenol compound (C) includes a compound represented by General Formula (8),

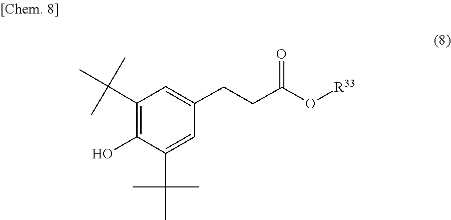

in General Formula (8), R³³ represents an organic group.

[9]

The cyclic olefin-based resin composition according to any one of [1] to [8], further containing:
an inorganic filler.

[10]

The cyclic olefin-based resin composition according to any one of [1] to [9], further containing:
a flame retardant.

[11]

A varnish containing:
the cyclic olefin-based resin composition according to any one of [1] to [10]; and
a solvent.

[12]

A crosslinked body of the cyclic olefin-based resin composition according to any one of [1] to [10].

[13]

A film or a sheet, including:
the crosslinked body according to [12].

[14]

A circuit board including:
an electrically insulating layer including the crosslinked body according to [12]; and
a conductor layer provided over the electrically insulating layer.

[15]

An electronic apparatus including:
the circuit board according to [14].

[16]

A prepreg containing:
the cyclic olefin-based resin composition according to any one of [1] to [10]; and
a sheet-shaped fiber base material.

### Advantageous Effects of Invention

With the above-described configuration of the cyclic olefin-based resin composition according to the aspect of the present invention, it is possible to provide a cyclic olefin-based resin composition in which both heat resistance and dielectric properties are compatible with each other.

### DESCRIPTION OF EMBODIMENTS

Hereinafter, the present invention will be described based on embodiments.

In the present embodiment, unless otherwise specified, “A to B” indicating a numerical range represents “equal to or more than A and equal to or less than B”.

In the present embodiment, a case in which a group such as an alkyl group “has a substituent” means that a hydrogen atom present in the structure of the group is substituted with a substituent, unless otherwise specified. The position of the substituent and the number of the substituents are not particularly limited. In a case where a substituent has carbon atoms, the number of carbon atoms in the substituent is not included in the number of carbon atoms in a group having the substituent. For example, an ethyl group having a phenyl group as the substituent is regarded as an alkyl group having 2 carbon atoms.

In the present embodiment, the solid content refers to components excluding volatile components such as a solvent.

### [Cyclic Olefin-Based Resin Composition]

The cyclic olefin-based resin composition according to the present embodiment contains:
a cyclic olefin-based copolymer (A);
an azo compound (B) which has an azo group in a molecule and includes no heteroatom other than a nitrogen atom constituting the azo group; and
a hindered phenol compound (C),
in which the cyclic olefin-based copolymer (A) includes a repeating unit (X) derived from one or more olefins represented by General Formula (1), a repeating unit (Y) derived from one or more cyclic non-conjugated dienes represented by General Formula (2), and a repeating unit (Z) derived from one or more cyclic olefins represented by General Formula (3),
an iodine value of the cyclic olefin-based copolymer (A) is in a range of equal to or more than 20 g/100 g and equal to or less than 120 g/100 g, and
a number-average molecular weight Mn of the cyclic olefin-based copolymer (A) is in a range of equal to or more than 3,000 and equal to or less than 30,000.

A detailed mechanism by which both heat resistance and dielectric properties are compatible with each other in the cyclic olefin-based resin composition according to the present embodiment is not clear, but it is presumed as follows.

That is, with the cyclic olefin-based resin composition according to the present embodiment, a sufficient amount of crosslinked structure can be formed by using the cyclic olefin-based copolymer having an iodine value within a specific range.

In addition, by using, as a radical initiator, a specific azo compound which does not generate a polar compound upon decomposition, it is possible to suppress deterioration of the dielectric properties due to the polar compound.

Furthermore, by using a hindered phenol compound as an antioxidant in combination and suppressing oxidation of a carbon-carbon double bond, it is possible to suppress deterioration of dielectric properties due to a polar group generated by the oxidation of the double bond.

As a result, it is presumed that both the heat resistance and the dielectric properties are compatible with each other.

Hereinafter, each component contained in the cyclic olefin-based resin composition according to the present embodiment will be described in detail.

### <Cyclic Olefin-Based Copolymer (A)>

The cyclic olefin-based copolymer (A) of the present embodiment includes a repeating unit derived from one or more olefins represented by General Formula (1), a repeating unit derived from one or more cyclic non-conjugated dienes represented by General Formula (2), and a repeating unit derived from one or more cyclic olefins represented by General Formula (3).

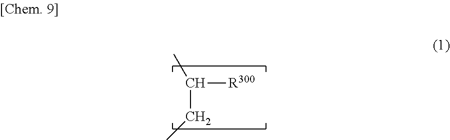

In General Formula (1), R³⁰⁰ represents a hydrogen atom or a linear or branched hydrocarbon group having 1 to 29 carbon atoms.

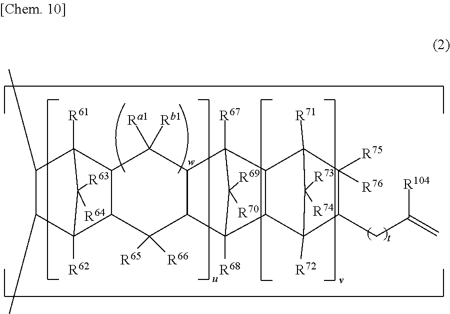

In General Formula (2), u is 0 or 1; v is 0 or a positive integer; w is 0 or 1; R⁶¹ to R⁷⁶, R^{a1}, and R^{b1} may be the same or different from each other, and are each a hydrogen atom, a halogen atom, an alkyl group having 1 to 20 carbon atoms, a halogenated alkyl group having 1 to 20 carbon atoms, a cycloalkyl group having 3 to 15 carbon atoms, or an aromatic hydrocarbon group having 6 to 20 carbon atoms; R¹⁰⁴ is a hydrogen atom or an alkyl group having 1 to 10 carbon atoms; t is a positive integer of 0 to 10; and R⁷⁵ and R⁷⁶ may be bonded to each other to form a monocyclic ring or a polycyclic ring.

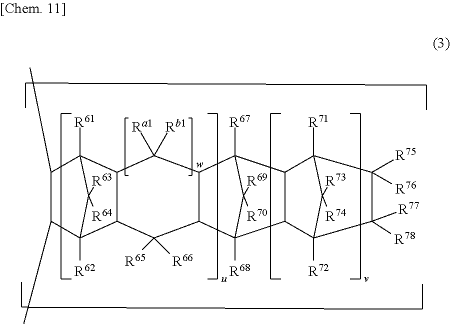

In General Formula (3), u is 0 or 1; v is 0 or a positive integer; w is 0 or 1; R⁶¹ to R⁷⁸, R^{a1}, and R^{b1} may be the same or different from each other, and are each a hydrogen atom, a halogen atom, an alkyl group having 1 to 20 carbon atoms, a halogenated alkyl group having 1 to 20 carbon atoms, a cycloalkyl group having 3 to 15 carbon atoms, or an aromatic hydrocarbon group having 6 to 20 carbon atoms; and R⁷⁵ to R⁷⁸ may be bonded to each other to form a monocyclic ring or a polycyclic ring.

The iodine value of the cyclic olefin-based copolymer (A) of the present embodiment is equal to or more than 20 g/100 g, preferably equal to or more than 25 g/100 g, more preferably equal to or more than 30 g/100 g, still more preferably equal to or more than 35 g/100 g, and even more preferably equal to or more than 40 g/100 g. As a result, a sufficient amount of crosslinking is formed in the crosslinked body, and the heat resistance and mechanical properties can be improved.

The iodine value of the cyclic olefin-based copolymer (A) of the present embodiment is equal to or less than 120 g/100 g, preferably equal to or less than 115 g/100 g, more preferably equal to or less than 112 g/100 g, still more preferably equal to or less than 100 g/100 g, and even still more preferably equal to or less than 80 g/100 g. As a result, generation of a carbonyl group or a carboxyl group, which is generated by the oxidation of the carbon-carbon double bond, can be suppressed, and thus the deterioration of dielectric properties due to the generation of these groups can be suppressed.

The iodine value of the cyclic olefin-based copolymer (A) of the present embodiment is in a range of equal to or more than 20 g/100 g and equal to or less than 120 g/100 g, preferably in a range of equal to or more than 25 g/100 g and equal to or less than 120 g/100 g, more preferably in a range of equal to or more than 30 g/100 g and equal to or less than 115 g/100 g, still more preferably in a range of equal to or more than 35 g/100 g and equal to or less than 115 g/100 g, and even more preferably in a range of equal to or more than 40 g/100 g and equal to or less than 112 g/100 g. As a result, the dielectric properties, heat resistance, and mechanical properties can be improved.

The iodine value of the cyclic olefin-based copolymer (A) can be controlled by selecting a copolymerization raw material, adjusting a feed ratio, and the like.

The number-average molecular weight Mn of the cyclic olefin-based copolymer (A) of the present embodiment is equal to or more than 3,000, preferably equal to or more than 3,500, more preferably equal to or more than 4,000, still more preferably equal to or more than 4,500, and still more preferably equal to or more than 5,000. As a result, the dielectric properties, heat resistance, and mechanical properties can be improved.

The number-average molecular weight Mn of the cyclic olefin-based copolymer (A) of the present embodiment is equal to or less than 30,000, preferably equal to or less than 25,000, more preferably equal to or less than 23,000, still more preferably equal to or less than 20,000, even more preferably equal to or less than 15,000, and even still more preferably equal to or less than 10,000. As a result, moldability such as impregnating properties and wiring embedding properties during manufacturing of a circuit board can be improved.

The number-average molecular weight Mn of the cyclic olefin-based copolymer (A) of the present embodiment is in a range of equal to or more than 3,000 and equal to or less than 30,000, preferably in a range of equal to or more than 3,500 and equal to or less than 25,000, more preferably in a range of equal to or more than 4,000 and equal to or less than 23,000, still more preferably in a range of equal to or more than 4,000 and equal to or less than 20,000, and even more preferably in a range of equal to or more than 4,000 and equal to or less than 10,000. As a result, the dielectric properties, heat resistance, and mechanical properties are improved, and the moldability is also improved.

The number-average molecular weight Mn of the cyclic olefin-based copolymer (A) can be controlled by polymerization conditions such as a polymerization catalyst, a co-catalyst, an H₂ addition amount, and a polymerization temperature.

A Tg of the cyclic olefin-based copolymer (A) is, for example, equal to or lower than 300° C., preferably equal to or lower than 250° C., more preferably equal to or lower than 200° C., still more preferably equal to or lower than 170° C., and even more preferably equal to or lower than 150° C. As a result, it is possible to improve melt moldability of the cyclic olefin-based copolymer (A) and solubility in a solvent in a case of being varnished.

The Tg of the cyclic olefin-based copolymer (A) is preferably equal to or higher than 70° C., more preferably equal to or higher than 80° C., and still more preferably equal to or higher than 90° C. As a result, the heat resistance of the cyclic olefin-based copolymer (A) can be improved.

The Tg of the cyclic olefin-based copolymer (A) can be controlled by selecting a copolymerization raw material, adjusting a feed ratio, and the like.

An intrinsic viscosity [ƒ] of the cyclic olefin-based copolymer (A), which is measured in decalin at 135° C., is preferably more than 0.01 dl/g, more preferably equal to or more than 0.02 dl/g, and still more preferably equal to or more than 0.04 dl/g. As a result, the heat resistance and mechanical properties can be further improved.

The intrinsic viscosity [ƒ] of the cyclic olefin-based copolymer (A), which is measured in decalin at 135° C., is preferably less than 0.45 dl/g, more preferably equal to or less than 0.40 dl/g, and still more preferably equal to or less than 0.35 dl/g. As a result, the moldability such as impregnating properties and wiring embedding properties during manufacturing of a circuit board can be further improved.

The intrinsic viscosity [ƒ] of the cyclic olefin-based copolymer (A) can be controlled by polymerization conditions such as a polymerization catalyst, a co-catalyst, a hydrogen addition amount, and a polymerization temperature.

A content of the cyclic olefin-based copolymer (A) in the cyclic olefin-based resin composition is preferably equal to or more than 5% by mass, more preferably equal to or more than 10% by mass, still more preferably equal to or more than 20% by mass, even more preferably equal to or more than 25% by mass, even still more preferably equal to or more than 30% by mass, further more preferably equal to or more than 40% by mass, even further more preferably equal to or more than 50% by mass, particularly preferably equal to or more than 60% by mass, and even particularly preferably equal to or more than 70% by mass.

The content of the cyclic olefin-based copolymer (A) in the cyclic olefin-based resin composition is preferably equal to or less than 99% by mass, more preferably equal to or less than 98% by mass, still more preferably equal to or less than 95% by mass, even more preferably equal to or less than 90% by mass, even still more preferably equal to or less than 80% by mass, and particularly preferably equal to or less than 75% by mass.

The cyclic olefin-based resin composition may contain a cyclic olefin-based copolymer other than the cyclic olefin-based copolymer (A) (hereinafter, referred to as other cyclic olefin-based copolymers (n)). The other cyclic olefin-based copolymers (n) will be described later.

In a case where the other cyclic olefin-based copolymers (n) are used in combination, the content of the cyclic olefin-based copolymer (A) with respect to the total amount of the cyclic olefin-based copolymer (A) and the other cyclic olefin-based copolymers (n) is preferably equal to or more than 5% by mass, more preferably equal to or more than 10% by mass, still more preferably equal to or more than 20% by mass, even more preferably equal to or more than 25% by mass, even still more preferably equal to or more than 30% by mass, further more preferably equal to or more than 40% by mass, even further more preferably equal to or more than 50% by mass, particularly preferably equal to or more than 60% by mass, and even particularly preferably equal to or more than 70% by mass.

In a case where the other cyclic olefin-based copolymers (n) are used in combination, the content of the cyclic olefin-based copolymer (A) with respect to the total amount of the cyclic olefin-based copolymer (A) and the other cyclic olefin-based copolymers (n) is preferably equal to or less than 95% by mass, more preferably equal to or less than 90% by mass, still more preferably equal to or less than 80% by mass, and particularly preferably equal to or less than 75% by mass.

A molar ratio of the repeating unit represented by General Formula (1) in the cyclic olefin-based copolymer (A) is preferably equal to or more than 30 mol %, more preferably equal to or more than 35 mol %, and still more preferably equal to or more than 40 mol %.

The molar ratio of the repeating unit represented by General Formula (1) in the cyclic olefin-based copolymer (A) is preferably equal to or less than 80 mol %, more preferably equal to or less than 75 mol %, and still more preferably equal to or less than 70 mol %.

The molar ratio of the repeating unit represented by General Formula (1) in the cyclic olefin-based copolymer (A) is preferably in a range of equal to or more than 30 mol % and equal to or less than 80 mol %, more preferably in a range of equal to or more than 35 mol % and equal to or less than 75 mol %, and still more preferably in a range of equal to or more than 40 mol % and equal to or less than 70 mol %.

A molar ratio of the repeating unit represented by General Formula (2) in the cyclic olefin-based copolymer (A) is preferably equal to or more than 1 mol %, more preferably equal to or more than 5 mol %, and still more preferably equal to or more than 10 mol %.

The molar ratio of the repeating unit represented by General Formula (2) in the cyclic olefin-based copolymer (A) is preferably equal to or less than 30 mol %, more preferably equal to or less than 25 mol %, and still more preferably equal to or less than 20 mol %.

The molar ratio of the repeating unit represented by General Formula (2) in the cyclic olefin-based copolymer (A) is preferably in a range of equal to or more than 1 mol % and equal to or less than 30 mol %, more preferably in a range of equal to or more than 5 mol % and equal to or less than 25 mol %, and still more preferably in a range of equal to or more than 10 mol % and equal to or less than 20 mol %.

A molar ratio of the repeating unit represented by General Formula (3) in the cyclic olefin-based copolymer (A) is preferably equal to or more than 1 mol %, more preferably equal to or more than 5 mol %, and still more preferably equal to or more than 10 mol %.

The molar ratio of the repeating unit represented by General Formula (3) in the cyclic olefin-based copolymer (A) is preferably equal to or less than 40 mol %, more preferably equal to or less than 35 mol %, and still more preferably equal to or less than 30 mol %.

The molar ratio of the repeating unit represented by General Formula (3) in the cyclic olefin-based copolymer (A) is preferably in a range of equal to or more than 1 mol % and equal to or less than 40 mol %, more preferably in a range of equal to or more than 5 mol % and equal to or less than 35 mol %, and still more preferably in a range of equal to or more than 10 mol % and equal to or less than 30 mol %.

A monomer which is one of the copolymerization raw materials of the cyclic olefin-based copolymer (A) is a monomer which forms the repeating unit represented by General Formula (1) by addition copolymerization, and specifically, the monomer is represented by General Formula (1a) corresponding to General Formula (1).

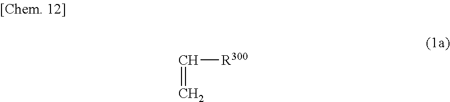

In General Formula (1a), R³⁰⁰ represents a hydrogen atom or a linear or branched hydrocarbon group having 1 to 29 carbon atoms.

The olefin represented by General Formula (1a) include, for example, ethylene, propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, and 1-eicosene.

From the viewpoint of obtaining a crosslinked body having more excellent heat resistance, mechanical properties, dielectric properties, transparency, and gas barrier properties, the olefin represented by General Formula (1a) is preferably ethylene and propylene, and particularly preferably ethylene.

Two or more kinds of the monomers represented by General Formula (1a) may be used. In addition, the olefin may include at least one biomass-derived monomer (biomass-derived ethylene, biomass-derived propylene, and the like).

A monomer which is one of the copolymerization raw materials of the cyclic olefin-based copolymer (A) is a monomer which forms the repeating unit represented by General Formula (2) by addition copolymerization, and specifically, the monomer is a cyclic non-conjugated diene represented by General Formula (2a) corresponding to General Formula (2). The above-described cyclic non-conjugated diene may include a constitutional unit derived from a biomass-derived monomer (cyclic non-conjugated diene).

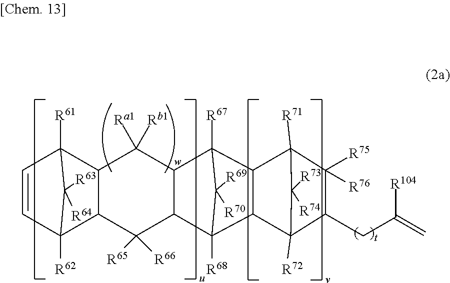

In General Formula (2a), u is 0 or 1; v is 0 or a positive integer, preferably an integer of equal to or more than 0 and equal to or less than 2 and more preferably 0 or 1; w is 0 or 1; R⁶¹ to R⁷⁶, R^{a1}, and R^{b1} may be the same or different from each other, and are each a hydrogen atom, a halogen atom, an alkyl group having 1 to 20 carbon atoms, a halogenated alkyl group having 1 to 20 carbon atoms, a cycloalkyl group having 3 to 15 carbon atoms, or an aromatic hydrocarbon group having 6 to 20 carbon atoms; R¹⁰⁴ is a hydrogen atom or an alkyl group having 1 to 10 carbon atoms; t is a positive integer of 0 to 10; and R⁷⁵ and R⁷⁶ may be bonded to each other to form a monocyclic ring or a polycyclic ring.

The cyclic non-conjugated diene represented by General Formula (2a) is not particularly limited, and examples thereof include cyclic non-conjugated dienes represented by the following chemical formulae.

Among these, 5-vinyl-2-norbornene or 8-vinyl-9-methyltetracyclo[4.4.0.1^{2,5}0.1^{7,10}]-3-dodecene is preferable, and 5-vinyl-2-norbornene is particularly preferable.

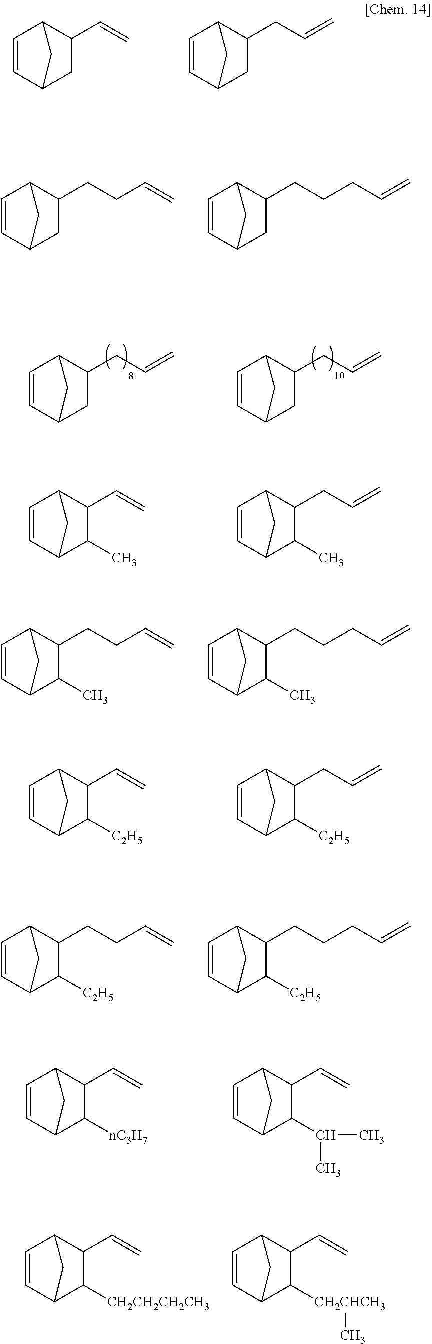

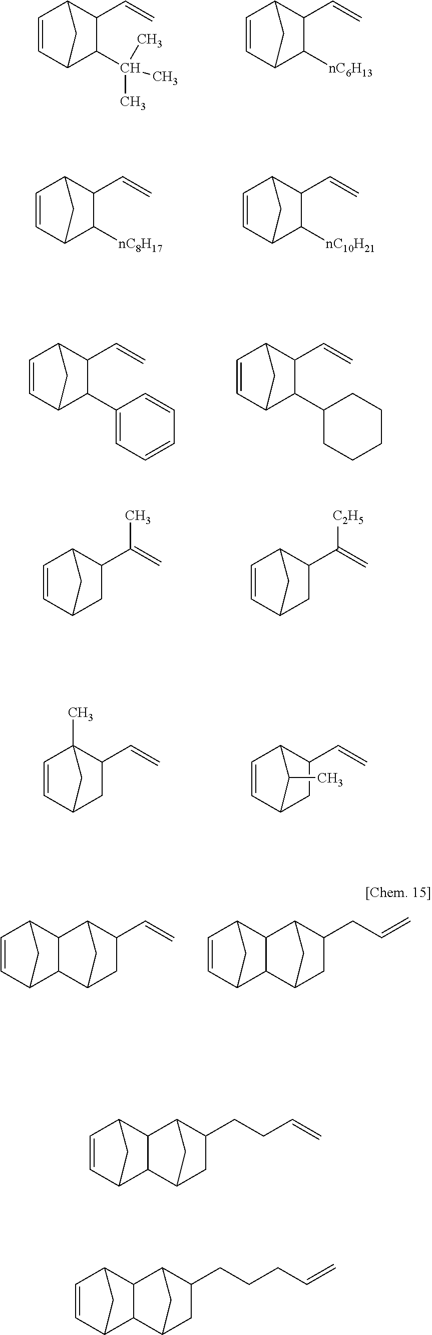

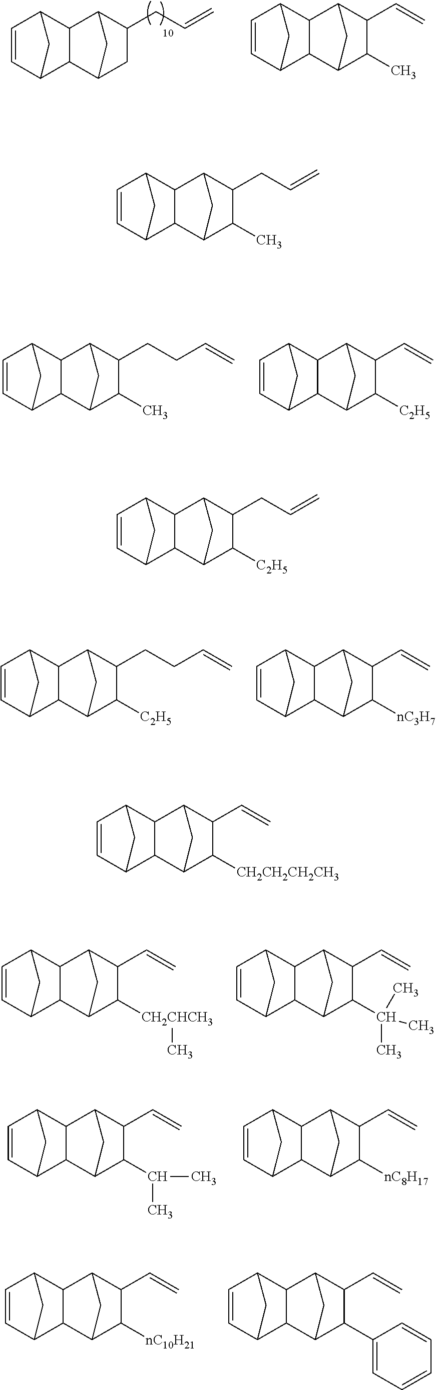

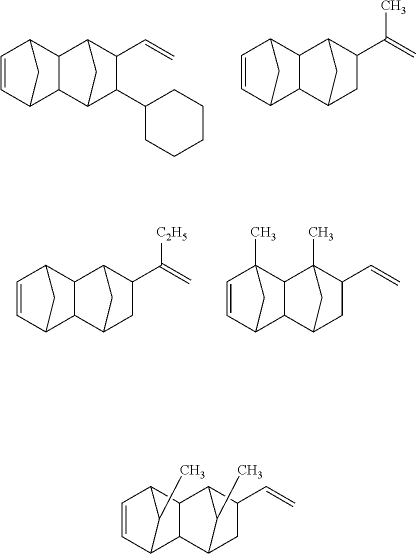

The cyclic non-conjugated diene represented by General Formula (2a) can be specifically represented by General Formula (2b).

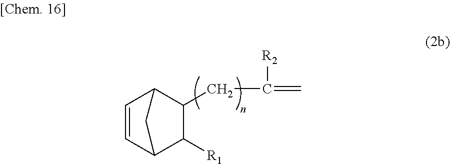

In General Formula (2b), n is an integer of 0 to 10; R₁ is a hydrogen atom or an alkyl group having 1 to 10 carbon atoms; and R₂ is a hydrogen atom or an alkyl group having 1 to 5 carbon atoms.

The cyclic olefin-based copolymer (A) of the present embodiment has a feature that, by including the repeating unit derived from the cyclic non-conjugated diene represented by General Formula (2), the cyclic olefin-based copolymer (A) has a double bond in a side chain portion. A crosslinked structure can be formed by the double bond.

A monomer which is one of the copolymerization raw materials of the cyclic olefin-based copolymer (A) is a monomer which forms the repeating unit represented by General Formula (3) by addition copolymerization, and specifically, the monomer is represented by General Formula (3a) corresponding to General Formula (3).

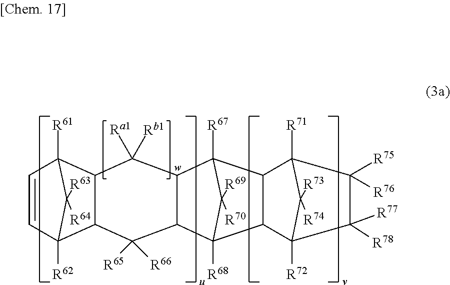

In General Formula (3a), u is 0 or 1; v is 0 or a positive integer, preferably an integer of equal to or more than 0 and equal to or less than 2 and more preferably 0 or 1; w is 0 or 1; R⁶¹ to R⁷⁸, R^{a1}, and R^{b1} may be the same or different from each other, and are each a hydrogen atom, a halogen atom, an alkyl group having 1 to 20 carbon atoms, a halogenated alkyl group having 1 to 20 carbon atoms, a cycloalkyl group having 3 to 15 carbon atoms, or an aromatic hydrocarbon group having 6 to 20 carbon atoms; and R⁷⁵ to R⁷⁸ may be bonded to each other to form a monocyclic ring or a polycyclic ring.

As a specific example of the cyclic olefin represented by General Formula (3a), compounds disclosed in International Publication No. WO2006/118261 can be used.

As the cyclic olefin represented by General Formula (3a), bicyclo[2.2.1]-2-heptene (also referred to as norbornene) or tetracyclo[4.4.0.1^{2,5}0.1^{7,10}]-3-dodecene (also referred to as tetracyclododecene) is preferable, and tetracyclo[4.4.0.1^{2,5}0.1^{7,10}]-3-dodecene is more preferable. Since these cyclic olefins have a rigid ring structure, a modulus of elasticity of the copolymer and the crosslinked body is easily retained, and since these cyclic olefins do not include a heterogeneous double bond structure, there is an advantage that crosslinking is easily controlled.

The above-described cyclic olefin represented by General Formula (3a) may include a constitutional unit derived from a biomass-derived monomer (cyclic olefin).

In a case where the monomer represented by General Formula (1a) and the monomer represented by General Formula (3a) are used as copolymer components, the solubility of the cyclic olefin-based copolymer (A) in a solvent is further improved, so that the moldability is improved and the yield of the product is improved.

As a combination of the copolymer components, it is preferable that the cyclic olefin-based copolymer (A) includes a repeating unit derived from 5-vinyl-2-norbornene as the repeating unit represented by General Formula (2), and includes at least one of a repeating unit derived from bicyclo[2.2.1]-2-heptene or a repeating unit derived from tetracyclo[4.4.0.1^{2,5}0.1^{7,10}]-3-dodecene as the repeating unit represented by General Formula (3). As a result, the dielectric properties, heat resistance, and mechanical properties can be improved.

The cyclic olefin-based copolymer (A) can be manufactured, for example, according to a manufacturing method of a cyclic olefin-based copolymer, disclosed in paragraphs 0075 to 0219 of International Publication No. WO2012/046443. Details will not be repeated here.

In the manufacturing of the cyclic olefin-based copolymer (A), a molar ratio of a feed amount of the monomer represented by General Formula (1a) is preferably equal to or more than 30 mol %, more preferably equal to or more than 35 mol %, and still more preferably equal to or more than 40 mol %.

In the manufacturing of the cyclic olefin-based copolymer (A), the molar ratio of the feed amount of the monomer represented by General Formula (1a) is preferably equal to or less than 80 mol %, more preferably equal to or less than 75 mol %, and still more preferably equal to or less than 70 mol %.

In the manufacturing of the cyclic olefin-based copolymer (A), the molar ratio of the feed amount of the monomer represented by General Formula (1a) is preferably in a range of equal to or more than 30 mol % and equal to or less than 80 mol %, more preferably in a range of equal to or more than 35 mol % and equal to or less than 75 mol %, and still more preferably in a range of equal to or more than 40 mol % and equal to or less than 70 mol % by.

In the manufacturing of the cyclic olefin-based copolymer (A), a molar ratio of a feed amount of the monomer represented by General Formula (2a) is preferably equal to or more than 1 mol %, more preferably equal to or more than 5 mol %, and still more preferably equal to or more than 10 mol %.

In the manufacturing of the cyclic olefin-based copolymer (A), the molar ratio of the feed amount of the monomer represented by General Formula (2a) is preferably equal to or less than 30 mol %, more preferably equal to or less than 25 mol %, and still more preferably equal to or less than 20 mol %.

In the manufacturing of the cyclic olefin-based copolymer (A), the molar ratio of the feed amount of the monomer represented by General Formula (2a) is preferably in a range of equal to or more than 1 mol % and equal to or less than 30 mol %, more preferably in a range of equal to or more than 5 mol % and equal to or less than 25 mol %, and still more preferably in a range of equal to or more than 10 mol % and equal to or less than 20 mol %.

In the manufacturing of the cyclic olefin-based copolymer (A), a molar ratio of a feed amount of the monomer represented by General Formula (3a) is preferably equal to or more than 1 mol %, more preferably equal to or more than 5 mol %, and still more preferably equal to or more than 10 mol %.

In the manufacturing of the cyclic olefin-based copolymer (A), the molar ratio of the feed amount of the monomer represented by General Formula (3a) is preferably equal to or less than 40 mol %, more preferably equal to or less than 35 mol %, and still more preferably equal to or less than 30 mol %.

In the manufacturing of the cyclic olefin-based copolymer (A), the molar ratio of the feed amount of the monomer represented by General Formula (3a) is preferably in a range of equal to or more than 1 mol % and equal to or less than 40 mol %, more preferably in a range of equal to or more than 5 mol % and equal to or less than 35 mol %, and still more preferably in a range of equal to or more than 10 mol % and equal to or less than 30 mol %.

### <Azo Compound (B)>

The cyclic olefin-based resin composition according to the present embodiment contains an azo compound (B) which has an azo group in a molecule and includes no heteroatom other than a nitrogen atom constituting the azo group.

The azo compound (B) is not particularly limited as long as it is an azo compound which has an azo group in the molecule and includes no heteroatom other than a nitrogen atom constituting the azo group.

The azo compound (B) generates a radical by heating, and thus functions as a radical initiator.

The azo compound (B) preferably includes a compound represented by General Formula (4).

[Chem. 18]

R²¹—N═N—R²² (4)

In General Formula (4), R²¹ and R²² each independently represent a hydrogen atom or an alkyl group.

In General Formula (4), the alkyl group represented by R²¹ and R²² does not include a heteroatom.

In General Formula (4), the alkyl group represented by R²¹ and R²² may be a linear alkyl group or a branched alkyl group.

Specific examples of the alkyl group include linear alkyl groups such as an n-propyl group, an n-butyl group, an n-pentyl group, an n-hexyl group, and an n-octyl group; and branched alkyl groups such as an s-butyl group, a t-butyl group, and a 2,2′,4,4′-tetramethylbutyl group.

Examples of a commercially available product of the azo compound (B) include VR-110 (2,2′-azobis(2,4,4-trimethylpentane); manufactured by FUJIFILM Wako Pure Chemical Corporation).

In General Formula (4), the number of carbon atoms in the alkyl group represented by R²¹ and R²² is preferably 1 to 8, more preferably 3 to 8, and still more preferably 4 to 8.

The azo compound (B) preferably includes at least one of a compound represented by Formula (5) or a compound represented by Formula (6).

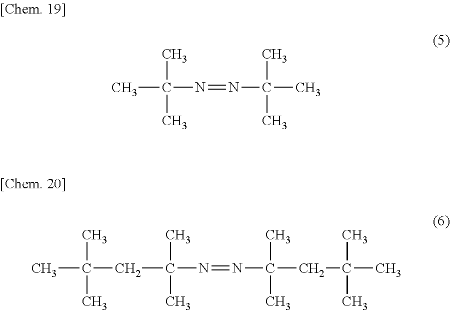

In a case where the total amount of the cyclic olefin-based copolymer (A) and the other cyclic olefin-based copolymers (n) is set to 100 parts by mass, a content of the azo compound (B) with respect to the total amount is preferably equal to or more than 0.1 parts by mass, more preferably equal to or more than 0.5 parts by mass, still more preferably equal to or more than 1 part by mass, even more preferably equal to or more than 1.5 parts by mass, and even still more preferably equal to or more than 2 parts by mass. As a result, crosslinking reaction can sufficiently proceed.

In a case where the total amount of the cyclic olefin-based copolymer (A) and the other cyclic olefin-based copolymers (n) is set to 100 parts by mass, the content of the azo compound (B) with respect to the total amount is preferably equal to or less than 20 parts by mass, more preferably equal to or less than 15 parts by mass, still more preferably equal to or less than 10 parts by mass, even more preferably equal to or less than 7 parts by mass, and even still more preferably equal to or less than 5 parts by mass. As a result, it is possible to prevent the deterioration of the dielectric properties.

In a case where the total amount of the cyclic olefin-based copolymer (A) and the other cyclic olefin-based copolymers (n) is set to 100 parts by mass, the content of the azo compound (B) with respect to the total amount is preferably in a range of equal to or more than 0.1 parts by mass and equal to or less than 20 parts by mass, more preferably in a range of equal to or more than 0.5 parts by mass and equal to or less than 15 parts by mass, still more preferably in a range of equal to or more than 1 part by mass and equal to or less than 10 parts by mass, even more preferably in a range of equal to or more than 1.5 parts by mass and equal to or less than 7 parts by mass, and even still more preferably in a range of equal to or more than 2 parts by mass and equal to or less than 5 parts by mass. As a result, it is possible to prevent the deterioration of the dielectric properties while sufficiently proceeding with the crosslinking reaction.

### <Hindered Phenol Compound (C)>

The cyclic olefin-based resin composition according to the present embodiment contains a hindered phenol compound (C).

The hindered phenol compound (C) preferably has a structure represented by General Formula (7).

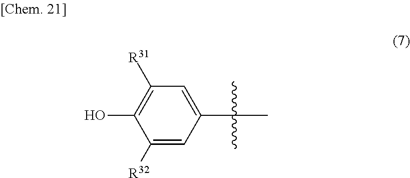

In General Formula (7), R³¹ represents an alkyl group having 1 to 4 carbon atoms; and R³² represents a hydrogen atom or an alkyl group having 1 to 4 carbon atoms.

In General Formula (7), R³¹ and R³² may or may not have a substituent.

Examples of the alkyl group having 1 to 4 carbon atoms, represented by R³¹, include a methyl group, an ethyl group, a propyl group, an isopropyl group, an isobutyl group, and a t-butyl group.

Examples of the hindered phenol compound (C) include pentaerythritol tetrakis[3-(3,5-di-tert-butyl-4-hydroxyphenyl)propionate](Irganox 1010 manufactured by BASF), octadecyl-3-(3,5-di-tert-butyl-4-hydroxyphenyl)propionate (Irganox 1076 manufactured by BASF), and 3,3′,3″,5,5′,5″-hexa-tert-butyl-a,a′,a″-(mesitylene-2,4,6-triyl)tri-p-cresol (Irganox 1330 manufactured by BASF).

In General Formula (7), it is preferable that R³¹ and R³² are both a t-butyl group. That is, in the present embodiment, it is preferable that the cyclic olefin-based resin composition contains a compound in which R³¹ and R³² in General Formula (7) are both a t-butyl group. As a result, oxidation degradation of a resin during processing can be suppressed, and thus the deterioration of dielectric properties can be prevented.

The hindered phenol compound (C) is preferably a compound represented by General Formula (8). As a result, dispersibility in the resin composition according to the embodiment of the present invention is improved, and the effect of suppressing the deterioration of the dielectric properties is enhanced.

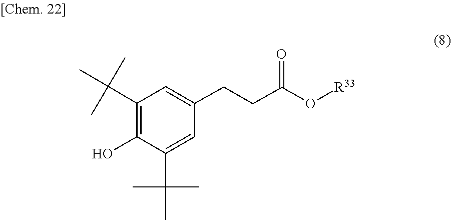

In General Formula (8), R³³ represents an organic group.

Examples of the organic group represented by R³³ include a substituted or unsubstituted alkyl group having 1 to 20 carbon atoms, a substituted or unsubstituted cyclohexyl group having 1 to 20 carbon atoms, and a substituted or unsubstituted aryl group having 6 to 20 carbon atoms.

Another substituted phenol structure may be linked through the organic group R³³.

Examples of the compound represented by General Formula (8) include pentaerythritol tetrakis[3-(3,5-di-tert-butyl-4-hydroxyphenyl)propionate](Irganox 1010 manufactured by BASF) and octadecyl-3-(3,5-di-tert-butyl-4-hydroxyphenyl)propionate (Irganox 1076 manufactured by BASF).

In a case where the total amount of the cyclic olefin-based copolymer (A) and the other cyclic olefin-based copolymers (n) is set to 100 parts by mass, a content of the hindered phenol compound (C) with respect to the total amount is preferably equal to or more than 0.001 parts by mass, more preferably equal to or more than 0.005 parts by mass, still more preferably equal to or more than 0.01 parts by mass, even more preferably equal to or more than 0.02 parts by mass, and even still more preferably equal to or more than 0.05 parts by mass.

As a result, the oxidation degradation of the cyclic olefin-based resin composition can be suppressed, and thus the deterioration of the dielectric properties can be prevented.

In a case where the total amount of the cyclic olefin-based copolymer (A) and the other cyclic olefin-based copolymers (n) is set to 100 parts by mass, the content of the hindered phenol compound (C) with respect to the total amount is preferably equal to or less than 1 part by mass, more preferably equal to or less than 0.5 parts by mass, still more preferably equal to or less than 0.2 parts by mass, even more preferably equal to or less than 0.1 parts by mass, and even still more preferably equal to or less than 0.08 parts by mass.

As a result, it is possible to suppress the inhibition of the crosslinking reaction of the cyclic olefin-based resin composition with the hindered phenol compound (C).

In a case where the total amount of the cyclic olefin-based copolymer (A) and the other cyclic olefin-based copolymers (n) is set to 100 parts by mass, the content of the hindered phenol compound (C) with respect to the total amount is preferably in a range of equal to or more than 0.001 parts by mass and equal to or less than 1 part by mass, more preferably in a range of equal to or more than 0.005 parts by mass and equal to or less than 0.5 parts by mass, still more preferably in a range of equal to or more than 0.01 parts by mass and equal to or less than 0.2 parts by mass, even more preferably in a range of equal to or more than 0.02 parts by mass and equal to or less than 0.1 parts by mass, and even still more preferably in a range of equal to or more than 0.05 parts by mass and equal to or less than 0.08 parts by mass.

As a result, it is possible to suppress the inhibition of the crosslinking reaction of the cyclic olefin-based resin composition with the hindered phenol compound (C), while preventing the deterioration of the dielectric properties.

### <Other Components>

The cyclic olefin-based resin composition according to the present embodiment may contain, as necessary, a cyclic olefin-based copolymer other than the cyclic olefin-based copolymer (A), a filler, a flame retardant, a crosslinking aid, and the like.

### (Other Cyclic Olefin-Based Copolymers (n))

Here, the cyclic olefin-based copolymer other than the above-described cyclic olefin-based copolymer (A) is referred to as other cyclic olefin-based copolymers (n). For example, a cyclic olefin-based copolymer not having the above-described requirement for the iodine value (an iodine value in a range of equal to or more than 20 g/100 g and equal to or less than 120 g/100 g) corresponds to the other cyclic olefin-based copolymers (n).

The cyclic olefin-based resin composition according to the present embodiment may contain the other cyclic olefin-based copolymers (n).

The other cyclic olefin-based copolymers (n) contained in the cyclic olefin-based resin composition according to the present embodiment are not particularly limited, and a known cyclic olefin-based copolymer can be used.

It is preferable that the other cyclic olefin-based copolymers (n) include at least one selected from a copolymer (n-i) of ethylene or an α-olefin with a cyclic olefin, or a ring-opening polymer (n-ii) of a cyclic olefin. As a result, the dielectric properties can be further improved.

It is preferable that the copolymer (n-i) does not include the repeating unit derived from the cyclic non-conjugated diene represented by General Formula (2) described above.

In the present embodiment, the fact that the above-described copolymer (n-i) does not include the repeating unit derived from the cyclic non-conjugated diene represented by General Formula (2) described above means that, in a case where the total molar amount of repeating units in the above-described copolymer (n-i) is set to 100 mol %, the content of the repeating unit derived from the cyclic non-conjugated diene represented by General Formula (2) described above is equal to or less than 0.05 mol %.

A number-average molecular weight Mn of the other cyclic olefin-based copolymers (n) is preferably equal to or more than 10,000. As a result, the dielectric properties, heat resistance, and mechanical properties can be further improved.

The number-average molecular weight Mn of the other cyclic olefin-based copolymers (n) is preferably equal to or less than 60,000, more preferably equal to or less than 57,000, and still more preferably equal to or less than 55,000. As a result, the moldability such as impregnating properties and wiring embedding properties during manufacturing of a circuit board can be further improved.

The number-average molecular weight Mn of the other cyclic olefin-based copolymers (n) can be controlled by polymerization conditions such as a polymerization catalyst, a co-catalyst, an H₂ addition amount, and a polymerization temperature.

A content of the other cyclic olefin-based copolymers (n) in the cyclic olefin-based resin composition is preferably equal to or more than 5% by mass, more preferably equal to or more than 10% by mass, still more preferably equal to or more than 20% by mass, and even more preferably equal to or more than 25% by mass.

The content of the other cyclic olefin-based copolymers (n) in the cyclic olefin-based resin composition is preferably equal to or less than 95% by mass, more preferably equal to or less than 90% by mass, still more preferably equal to or less than 80% by mass, and even more preferably equal to or less than 75% by mass.

The content of the other cyclic olefin-based copolymers (n) with respect to the total amount of the cyclic olefin-based copolymer (A) and the other cyclic olefin-based copolymers (n) is preferably equal to or more than 5% by mass, more preferably equal to or more than 10% by mass, still more preferably equal to or more than 20% by mass, and even more preferably equal to or more than 25% by mass.

The content of the other cyclic olefin-based copolymers (n) with respect to the total amount of the cyclic olefin-based copolymer (A) and the other cyclic olefin-based copolymers (n) is preferably equal to or less than 95% by mass, more preferably equal to or less than 90% by mass, still more preferably equal to or less than 80% by mass, and even more preferably equal to or less than 75% by mass.

As the copolymer (n-i) of ethylene or an α-olefin with a cyclic olefin, for example, polymers described in paragraphs 0030 to 0123 of International Publication No. WO2008/047468 can be used.

For example, the above-described copolymer (n-i) is a polymer having an alicyclic structure in at least a part of the repeating structural units (hereinafter, also simply referred to as “polymer having an alicyclic structure”), it is sufficient that the polymer has an alicyclic structure in at least a part of the repeating units of the polymer, and specifically, it is preferable to include a polymer having one or two or more structures represented by General Formula (13).

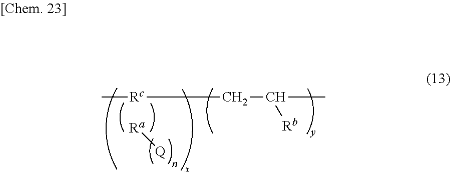

In General Formula (13), x and y represent a copolymerization ratio, and are real numbers satisfying 0/100≤y/x≤95/5; x and y are on a molar basis; n represents the number of substituents of a substituent Q, and is a real number of 0≤n≤2; R^{a} is a (2+n)-valent group selected from the group consisting of a hydrocarbon group having 2 to 20 carbon atoms; R^{b} is a hydrogen atom or a monovalent group selected from the group consisting of a hydrocarbon group having 1 to 10 carbon atoms; R^{c} is a tetravalent group selected from the group consisting of a hydrocarbon group having 2 to 10 carbon atoms; Q is COOR^{d} (R^{d} is a hydrogen atom or a monovalent group selected from the group consisting of a hydrocarbon group having 1 to 10 carbon atoms); and R^{a}, R^{b}, R^{c}, and Q may be each one kind or two or more kinds at an optional proportion.

In General Formula (13), R^{a} is preferably one kind or two or more kinds of divalent groups selected from a hydrocarbon group having 2 to 12 carbon atoms, more preferably a divalent group represented by General Formula (17) in a case where n is 0, and still more preferably a divalent group in which p in General Formula (17) is 0 or 1. As the structure of R^{a}, one kind may be used alone, or two or more kinds may be used in combination.

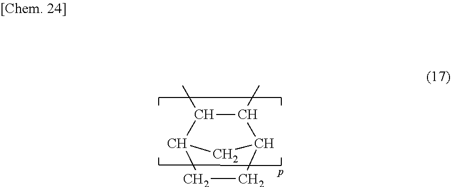

In General Formula (17), p is an integer of 0 to 2.

In addition, examples of the copolymer (n-i) of ethylene or an α-olefin with a cyclic olefin include a cyclic olefin-based copolymer represented by General Formula (14).

The cyclic olefin-based copolymer represented by General Formula (14) includes, for example, a repeating unit derived from ethylene or a linear or branched α-olefin having 3 to 30 carbon atoms, and a repeating unit derived from a cyclic olefin.

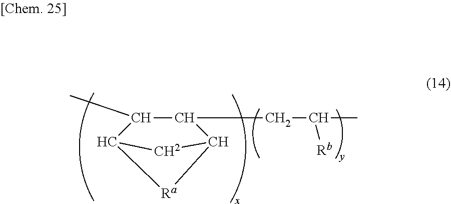

In General Formula (14), R^{a} is a divalent group selected from the group consisting of a hydrocarbon group having 2 to 20 carbon atoms; R^{b} is a hydrogen atom or a monovalent group selected from the group consisting of a hydrocarbon group having 1 to 10 carbon atoms; R^{a} and R^{b} may be each one kind or two or more kinds at an optional proportion; and x and y represent a copolymerization ratio (on a molar basis), and are real numbers satisfying 5/95≤y/x≤95/5, preferably 50/50≤y/x≤95/5 and more preferably 55/45≤y/x≤80/20.

The copolymer (n-i) of ethylene or an α-olefin with a cyclic olefin is preferably a copolymer including ethylene and a cyclic olefin; more preferably a copolymer in which the cyclic olefin is one kind or two or more kinds selected from the group consisting of bicyclo[2.2.1]-2-heptene, tetracyclo [4.4.0.1^{2,5}0.1^{7,10}]-3-dodecene, 1,4-methano-1,4,4a, 9a-tetrahydrofluorene, cyclopentadiene-benzyne adduct, and cyclopentadiene-acenaphthylene adduct; and still more preferably a copolymer in which the cyclic olefin is at least one selected from bicyclo[2.2.1]-2-heptene or tetracyclo[4.4.0.1^{2,5}0.1^{7,10}]-3-dodecene.

The copolymer (n-i) of ethylene or an α-olefin with a cyclic olefin may be a polymer having one or two or more kinds of structures represented by General Formula (13), or a polymer in which the cyclic olefin-based copolymer represented by General Formula (14) is hydrogenated.

In addition, as the copolymer (n-i) of ethylene or an α-olefin with a cyclic olefin, a copolymer of an α-olefin having 4 to 12 carbon atoms and a cyclic olefin is also preferable. As the copolymer of an α-olefin having 4 to 12 carbon atoms and a cyclic olefin, for example, polymers described in paragraphs 0056 to 0070 of International Publication No. WO2015/178145 can be used.

The cyclic olefin constituting the copolymer of an α-olefin having 4 to 12 carbon atoms and a cyclic olefin include, for example, norbornene and substituted norbornene, and norbornene is preferable. The above-described cyclic olefin may be used alone or in a combination of two or more kinds thereof.

The above-described substituted norbornene is not particularly limited, and a substituent of the substituted norbornene include, for example, a halogen atom and a monovalent or divalent hydrocarbon group. Specific examples of the substituted norbornene include a compound represented by General Formula (a).

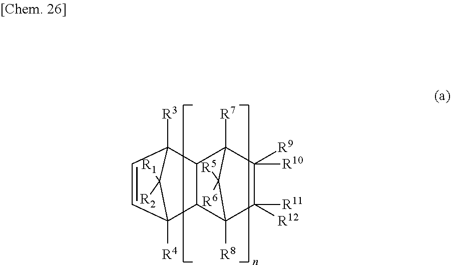

In General Formula (a), R¹ to R¹², which may be the same or different from each other, are selected from the group consisting of a hydrogen atom, a halogen atom, and a hydrocarbon group; R⁹ and R¹⁰, or R¹¹ and R¹² may be integrated with each other to form a divalent hydrocarbon group; and R⁹ or R¹⁰, and R¹¹ or R¹² may form a ring with each other. In addition, n represents 0 or a positive integer, and in a case where n is equal to or more than 2, R⁵ to R⁸ may be the same or different from each other in each of repeating units. However, in a case where n=0, at least one of R¹ to R⁴ or R⁹ to R¹² is not a hydrogen atom.

The substituted norbornene represented by General Formula (a) will be described.

R¹ to R¹² in General Formula (a) may be the same or different from each other, and are each selected from the group consisting of a hydrogen atom, a halogen atom, and a hydrocarbon group.

Specific examples of R¹ to R⁸ include, for example, a hydrogen atom, a halogen atom such as fluorine, chlorine, and bromine, and an alkyl group having 1 to 20 carbon atoms; and these may be different from each other, may be partially different from each other, or may be all the same.

In addition, specific examples of R⁹ to R¹² include, for example, a hydrogen atom; a halogen atom such as fluorine, chlorine, and bromine; an alkyl group having 1 to 20 carbon atoms; a cycloalkyl group such as a cyclohexyl group; a substituted or unsubstituted aromatic hydrocarbon group such as a phenyl group, a tolyl group, an ethylphenyl group, an isopropylphenyl group, a naphthyl group, and an anthryl group; and an aralkyl group in which an alkyl group is substituted with an aryl group, such as a benzyl group and a phenethyl group. These groups may be different from each other, may be partially different from each other, or may be all the same.

Specific examples of a case in which R⁹ and R¹⁰, or R¹¹ and R¹² are integrated with each other to form a divalent hydrocarbon group include, for example, an alkylidene group such as an ethylidene group, a propylidene group, and an isopropylidene group.

In a case where R⁹ or R¹⁰, and R¹¹ or R¹² forms a ring with each other, the ring to be formed may be a monocyclic ring or a polycyclic ring, may be a polycyclic ring having a crosslinking, may be a ring having a double bond, or may be a ring including a combination of these rings. In addition, these rings may have a substituent such as a methyl group.

Specific examples of the substituted norbornene represented by General Formula (a) include cyclic olefins with two rings, such as 5-methyl-bicyclo[2.2.1]hept-2-ene, 5,5-dimethyl-bicyclo[2.2.1]hept-2-ene, 5-ethyl-bicyclo[2.2.1]hept-2-ene, 5-butyl-bicyclo[2.2.1]hept-2-ene, 5-ethylidene-bicyclo[2.2.1]hept-2-ene, 5-hexyl-bicyclo[2.2.1]hept-2-ene, 5-octyl-bicyclo[2.2.1]hept-2-ene, 5-octadecyl-bicyclo[2.2.1]hept-2-ene, 5-methylidene-bicyclo[2.2.1]hept-2-ene, 5-vinyl-bicyclo[2.2.1]hept-2-ene, and 5-propenyl-bicyclo[2.2.1]hept-2-ene; tricyclo[4.3.0.1^{2,5}]deca-3,7-diene (common name: dicyclopentadiene), tricyclo[4.3.0.1^{2,5}]dec-3-ene; tricyclo[4.4.0.1^{2,5}]undeca-3-ene which is tricyclo[4.4.0.1^{2,5}]undeca-3,7-diene, tricyclo[4.4.0.1^{2,5}]undeca-3,8-diene, or partial hydrogenated products thereof (or an adduct of cyclopentadiene and cyclohexene); cyclic olefins with three rings such as 5-cyclopentyl-bicyclo[2.2.1]hept-2-ene, 5-cyclohexyl-bicyclo[2.2.1]hept-2-ene, 5-cyclohexenylbicyclo[2.2.1]hept-2-ene, and 5-phenyl-bicyclo[2.2.1]hept-2-ene; cyclic olefins with four rings such as tetracyclo[4.4.0.1^{2,5}0.1^{7,10}]dodeca-3-ene (also simply referred to as tetracyclododecene), 8-methyltetracyclo[4.4.0.1^{2,5}0.1^{7,10}]dodeca-3-ene, 8-ethyltetracyclo[4.4.0.1^{2,5}0.1^{7,10}]dodeca-3-ene, 8-methylidenetetracyclo[4.4.0.1^{2,5}0.1^{7,10}]dodeca-3-ene, 8-ethylidenetetracyclo[4.4.0.1^{2,5}0.1^{7,10}]dodeca-3-ene, 8-vinyltetracyclo[4,4.0.1^{2,5}0.1^{7,10}]dodeca-3-ene, and 8-propenyl-tetracyclo[4.4.0.1^{2,5}0.1^{7,10}]dodeca-3-ene; 8-cyclopentyl-tetracyclo[4.4.0.1^{2,5}0.1^{7,10}]dodeca-3-ene, 8-cyclohexyl-tetracyclo[4.4.0.1^{2,5}0.1^{7,10}]dodeca-3-ene, 8-cyclohexenyl-tetracyclo[4.4.0.1^{2,5}0.1^{7,10}]dodeca-3-ene, and 8-phenyl-cyclopentyl-tetracyclo [4.4.0.1^{2,5}0.1^{7,10}]dodeca-3-ene; tetracyclo[7.4.1^{3,6}0.0^{1,9}0.0^{2,7}]tetradeca-4,9,11,13-tetraene (also referred to as 1,4-methano-1,4,4a,9a-tetrahydrofluorene), tetracyclo[8.4.1^{4,7}0.0^{1,10}0.0^{3,8}]pentadeca-5,10,12,14-tetraene (also referred to as 1,4-methano-1,4,4a,5,10,10a-hexahydroanthracene); pentacyclo[6.6.1.1^{3,6}0.0^{2,7}0.0^{9,14}]-4-hexadecene, pentacyclo[6.5.1.1^{3,6}0.0^{2,7}0.0^{9,13}]-4-pentadecene, pentacyclo [7.4.0.0^{2,7}0.1^{3,6}0.1^{10,13}]-4-pentadecene; heptacyclo [8.7.0.1^{2,9}0.1^{4,7}0.1^{11,17}0.0^{3,8}0.0^{12,16}]-5-eicosene, heptacyclo [8.7.0.1^{2,9}0.0^{3,8}0.1^{4,7}0.0^{12,17}0.1^{13,16}]-14-eicosene; and polycyclic cyclic olefins such as tetramers of cyclopentadiene.

Among the above, alkyl-substituted norbornenes (for example, bicyclo[2.2.1]hepta-2-ene substituted with one or more alkyl groups) or alkylidene-substituted norbornenes (for example, bicyclo[2.2.1]hept-2-ene substituted with one or more alkylidene groups) are preferable; and 5-ethylidene-bicyclo[2.2.1]hepta-2-ene (common name: 5-ethylidene-2-norbornene or simply ethylidene norbornene) are particularly preferable.

Examples of the α-olefin having 4 to 12 carbon atoms, which constitutes the copolymer of an α-olefin having 4 to 12 carbon atoms and a cyclic olefin, include an α-olefin having 4 to 12 carbon atoms and an α-olefin having 4 to 12 carbon atoms and having at least one substituent such as a halogen atom. Among the above, an α-olefin having 4 to 12 carbon atoms is preferable.

The α-olefin having 4 to 12 carbon atoms is not particularly limited, and examples thereof include 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, and 1-dodecene. Among the above, 1-hexene, 1-octene, or 1-decene is preferable.

In the copolymer of an α-olefin having 4 to 12 carbon atoms and a cyclic olefin according to the present embodiment, in a case where the total of repeating units included in the copolymer is set to 100 mol %, a proportion of a repeating unit derived from the α-olefin having 4 to 12 carbon atoms is preferably equal to or more than 10 mol % and equal to or less than 90 mol %, more preferably equal to or more than 15 mol % and equal to or less than 80 mol %, and still more preferably equal to or more than 20 mol % and equal to or less than 70 mol %.

In addition, in the copolymer of an α-olefin having 4 to 12 carbon atoms and a cyclic olefin according to the present embodiment, in a case where the total of repeating units included in the copolymer is set to 100 mol %, a proportion of a repeating unit derived from the cyclic olefin is preferably equal to or more than 10 mol % and equal to or less than 90 mol %, more preferably equal to or more than 20 mol % and equal to or less than 85 mol %, and still more preferably equal to or more than 30 mol % and equal to or less than 80 mol %.

Conditions of a polymerization step for obtaining the copolymer of an α-olefin having 4 to 12 carbon atoms and a cyclic olefin are not particularly limited as long as the desired copolymer is obtained, and known conditions can be used in which the polymerization temperature, the polymerization pressure, the polymerization time, and the like are appropriately adjusted.

In addition, as the other cyclic olefin-based copolymers (n), a ring-opening polymer (n-ii) of a cyclic olefin can be used.

The ring-opening polymer (n-ii) of a cyclic olefin include, for example, a ring-opening polymer of a norbornene-based monomer, a ring-opening polymer of a norbornene-based monomer and other monomers capable of ring-opening copolymerization with the norbornene-based monomer, and hydrogenated products thereof.

The norbornene-based monomer include, for example, bicyclo[2.2.1]hept-2-ene (common name: norbornene) and derivatives thereof (having a substituent in a ring thereof), tricyclo[4.3.0^{1,6}0.1^{2,5}]-deca-3,7-diene (common name: dicyclopentadiene) and derivatives thereof, 7,8-benzotricyclo[4.3.0.1^{2,5}]deca-3-ene (common name: metanotetrahydrofluorene, also referred to as 1,4-methano-1,4,4a,9a-tetrahydrofluorene) and derivatives thereof, and tetracyclo[4.4.0.1^{2,5}0.1^{7,10}]-3-dodecene (common name: tetracyclododecene) and derivatives thereof. Examples of a substituent substituted to a ring of each derivative include an alkyl group, an alkylene group, a vinyl group, an alkoxycarbonyl group, and an alkylidene group. The norbornene-based monomer may have one or two or more substituents. The derivative having the substituent contained in such a ring include, for example, 8-methoxycarbonyl-tetracyclo[4.4.0.1_{2,5}0.1^{7,10}]dodeca-3-ene, 8-methyl-8-methoxycarbonyl-tetracyclo [4.4.0.1^{2,5}0.1^{7,10}]dodeca-3-ene, and 8-ethylidene-tetracyclo[4.4.0.1^{2,5}0.1^{7,10}]dodeca-3-ene.

These norbornene-based monomers are each used alone or in combination of two or more kinds thereof.

The ring-opening polymer of the norbornene-based monomer or the ring-opening polymer of the norbornene-based monomer and other monomers capable of ring-opening copolymerization with the norbornene-based monomer can be obtained by polymerization of a monomer component in the presence of a known ring-opening polymerization catalyst.

As the ring-opening polymerization catalyst, for example, a catalyst consisting of a metal halide of ruthenium, osmium, or the like, a nitrate or an acetylacetone compound, and a reducing agent; and a catalyst consisting of a metal halide of titanium, zirconium, tungsten, molybdenum, or the like or an acetylacetone compound and an organoaluminum compound; and the like can be used.

The other monomers capable of ring-opening copolymerization with the norbornene-based monomer include, for example, monocyclic cyclic olefin monomers such as cyclohexene, cycloheptene, and cyclooctene.

A hydrogenated product of the ring-opening polymer of the norbornene-based monomer or a hydrogenated product of the ring-opening polymer of the norbornene-based monomer and other monomers capable of ring-opening copolymerization with the norbornene-based monomer can be usually obtained by a method in which a known hydrogenation catalyst containing a transition metal such as nickel or palladium is added to a polymerization solution of the ring-opening polymer, and a carbon-carbon unsaturated bond is subjected to hydrogenation.

In the present embodiment, one kind of the other cyclic olefin-based copolymers (n) may be used alone, or two or more kinds thereof may be used in combination.

### (Filler)

The cyclic olefin-based resin composition according to the present embodiment may contain a filler.

The filler contained in the cyclic olefin-based resin composition according to the present embodiment is not particularly limited, and a known filler can be used.

The filler may be used alone or in combination of a plurality of kinds thereof.

An addition amount of the filler is appropriately selected depending on the application within a range that does not impair the object of the present invention.

The filler includes, for example, an inorganic filler and an organic filler.

The inorganic filler includes, for example, silica. In addition, inorganic fillers exemplified in paragraph [0117] of Pamphlet of International Publication No. WO2017/150218 can be used.

The organic filler includes, for example, starch and a derivative thereof. In addition, organic fillers exemplified in paragraph [0118] of Pamphlet of International Publication No. WO2017/150218 can be used.

It is preferable that the cyclic olefin-based resin composition according to the present embodiment contains the inorganic filler.

### (Flame Retardant)

The cyclic olefin-based resin composition according to the present embodiment may contain a flame retardant.

The flame retardant contained in the cyclic olefin-based resin composition according to the present embodiment is not particularly limited, and a known flame retardant can be used.

The flame retardant may be used alone or in combination of a plurality of kinds thereof.

An addition amount of the flame retardant is appropriately selected depending on the application within a range that does not impair the object of the present invention.

As the flame retardant, for example, a halogen-based flame retardant, a phosphorus-based flame retardant, a nitrogen-containing flame retardant, or an antimony-based flame retardant can be used.

As the halogen-based flame retardant, various flame retardants such as a chlorine-based flame retardant and a bromine-based flame retardant can be used, but from the viewpoint of flame retardant effect, heat resistance during molding, dispersibility in the resin, and influence on physical properties of the resin, pentabromodiphenyl ether and the like ae exemplified. In addition, flame retardants exemplified in paragraph [0105] of Pamphlet of International Publication No. WO2017/150218 can be used.

The phosphorus-based flame retardant includes, for example, tris(chloroethyl) phosphate. In addition, phosphorus-based flame retardants exemplified in paragraph [0106] of Pamphlet of International Publication No. WO2017/150218 can be used.

It is preferable that the cyclic olefin-based resin composition according to the present embodiment contains the flame retardant.

### (Crosslinking Aid)

The cyclic olefin-based resin composition according to the present embodiment may contain a crosslinking aid.

The crosslinking aid contained in the cyclic olefin-based resin composition according to the present embodiment is not particularly limited, and a known crosslinking aid can be used.

The crosslinking aid may be used alone or in combination of a plurality of kinds thereof.

An addition amount of the crosslinking aid is appropriately selected depending on the application within a range that does not impair the object of the present invention.

The crosslinking aid includes, for example, oximes such as p-quinonedioxime and p,p′-dibenzoylquinonedioxime; acrylates or methacrylates such as ethylene dimethacrylate, polyethylene glycol dimethacrylate, trimethylolpropane trimethacrylate, cyclohexyl methacrylate, acrylic acid/zinc oxide mixture, and allyl methacrylate; vinyl monomers such as divinylbenzene, vinyltoluene, and vinylpyridine; allyl compounds such as hexamethylene diallyl nadimide, diallyl itaconate, diallyl phthalate, diallyl isophthalate, diallyl monoglycidyl isocyanurate, triallyl cyanurate, and triallyl isocyanurate; maleimide compounds such as N,N′-m-phenylene bismaleimide and N,N′-(4,4′-methylene diphenylene)dimaleimide, cyclic non-conjugated dienes such as vinyl norbornene, ethylidene norbornene, and dicyclopentadiene.

The cyclic olefin-based resin composition according to the present embodiment may contain, in addition to the above-described components, various additives such as a heat stabilizer, a weather stabilizer, a radiation resistant agent, a plasticizer, a lubricant, a release agent, a nucleating agent, a friction abrasion resistance improver, a foaming agent, an antistatic agent, a colorant, an antifogging agent, an antiblocking agent, an impact resistance improver, a surface wetting improver, a hydrochloric acid absorbent, and a metal deactivator, as necessary.

### <Physical Properties>

A glass transition point (Tg) of a crosslinked body of the cyclic olefin-based resin composition according to the present embodiment is preferably equal to or higher than 80° C. more preferably equal to or higher than 90° C., still more preferably equal to or higher than 100° C., and even more preferably equal to or higher than 110° C. As a result, the heat resistance can be improved.

The upper limit of the Tg of the crosslinked body is not particularly limited, but can be, for example, equal to or lower than 300° C.

A dielectric loss tangent (Df) of a crosslinked body of the cyclic olefin-based resin composition according to the present embodiment at 10 GHz is preferably equal to or less than 0.00100, more preferably equal to or less than 0.00095, still more preferably equal to or less than 0.00090, even more preferably equal to or less than 0.00085, and even still more preferably equal to or less than 0.00080.

The lower limit of the Df of the crosslinked body is not particularly limited, but is, for example, equal to or more than 0.00001.

The crosslinked body used for measuring the glass transition point and the dielectric loss tangent can be obtained, for example, by crosslinking the cyclic olefin-based copolymer of the present embodiment under the following conditions.

The cyclic olefin-based resin composition according to the present embodiment is applied onto a PET film subjected to a mold release treatment in a molten state at a rate of 10 mm/sec, and then dried in a nitrogen stream hot air dryer at 150° C. for 4 minutes to obtain a film-like crosslinking precursor. Two obtained crosslinking precursors are stacked, pressurized to 3.5 MPa by a vacuum press, heated from room temperature (25° C.) at a constant rate, and held at 180° C. for 120 minutes, thereby obtaining a film-like crosslinked body.

### <Applications>

Since the cyclic olefin-based resin composition according to the present embodiment is excellent in solvent resistance, heat resistance, mechanical strength, and transparency, the cyclic olefin-based resin composition can be used for applications such as optical fibers, optical waveguides, optical disc substrates, optical filters, lenses, optical adhesives, PDP optical filters, coating materials for organic EL, base film base materials for solar cells in the aerospace field, coating materials for solar cells and thermal control systems, semiconductor elements, light emitting diodes, electronic elements such as various types of memory, a hybrid IC, an MCM, a circuit board, a prepreg or a laminate used for forming an insulating layer of a circuit substrate, overcoat materials or interlayer insulating materials for display components or the like, substrates for liquid crystal displays or solar cells, medical instruments, automobile members, mold releasing agents, resin modifiers, transparent substrates for displays, members for lithium-ion batteries, semiconductor process members, film capacitors, gas barrier coating materials, electric wire coating materials, automobile members, aerospace members, process materials for semiconductors, wire coating materials, members for lithium-ion batteries, members for fuel cells, capacitor films, flexible display members, anchor coat materials, transparent adhesives, modified materials, crosslinking aids, medical containers, medical catheter members, waterproof sealing materials, releasing materials, hard coat materials, and foam modifiers.

The cyclic olefin-based resin composition according to the present embodiment is particularly excellent in temporal stability of dielectric properties, and is also excellent in solvent resistance, heat resistance, transparency, mechanical properties, and the like. Therefore, the cyclic olefin-based resin composition according to the present embodiment can be suitably used for high-frequency applications such as a high-frequency circuit board. Furthermore, since the cyclic olefin-based resin composition according to the present embodiment is excellent in gas barrier properties, the cyclic olefin-based resin composition according to the present embodiment can be suitably used for a substrate, film, or sheet for liquid crystal displays and solar cells.

### [Varnish]

The varnish according to the present embodiment contains the above-described cyclic olefin-based resin composition, and a solvent.

The solvent for preparing the varnish according to the present embodiment is not particularly limited as long as it does not impair solubility or affinity of the cyclic olefin-based copolymer (A).

For example, saturated hydrocarbons such as heptane, hexane, octane, and decane; alicyclic hydrocarbons such as cyclohexane, methylcyclohexane, and decahydronaphthalene; aromatic hydrocarbons such as toluene, benzene, xylene, mesitylene, and pseudocumene; alcohols such as methanol, ethanol, isopropyl alcohol, butanol, pentanol, hexanol, propanediol, and phenol; ketone solvents such as acetone, methyl isobutyl ketone, methyl ethyl ketone, pentanone, hexanone, cyclohexanone, isophorone, and acetophenone; cellosolves such as methyl cellosolve and ethyl cellosolve; esters such as methyl acetate, ethyl acetate, butyl acetate, methyl propionate, and butyl formate; halogenated hydrocarbons such as trichloroethylene, dichloroethylene, and chlorobenzene; or the like can be used. Preferred examples thereof include heptane, decane, cyclohexane, methylcyclohexane, decahydronaphthalene, toluene, benzene, xylene, mesitylene, and pseudocumene.

It is possible to use these solvents alone or as a mixture of two or more thereof at an optional proportion.

In the present embodiment, as a method of manufacturing the varnish, any method may be performed, but usually, a step of mixing the cyclic olefin-based resin composition and the solvent is included. The order of the components in the mixing of the respective components is not limited, and the mixing can be carried out in any manner such as all at once or in portions. An apparatus for preparing the varnish is also not limited, and the preparation may be carried out by any batch type or continuous type apparatus capable of stirring and mixing. It is possible to arbitrarily select a temperature when preparing the varnish, within a range from room temperature to a boiling point of the solvent.

In addition, after the mixing, filtration may be further carried out using a mesh, a membrane filter, or the like.

### [Crosslinked Body]

The crosslinked body according to the present embodiment is a crosslinked body of the above-described cyclic olefin-based resin composition.

The crosslinked body according to the present embodiment can be obtained by crosslinking the above-described cyclic olefin-based resin composition, the above-described varnish, a prepreg, and the like.

The crosslinking reaction can also be carried out after the molten cyclic olefin resin composition is molded by any method, or after the molten cyclic olefin resin composition is impregnated in a base material to be in a prepreg state.

For example, a film-like crosslinking precursor can be obtained by forming a molten cyclic olefin resin composition by any method and cooling the composition, and then the obtained crosslinking precursor can be subjected to a heating or the like to proceed the crosslinking reaction.

In addition, a film-like crosslinking precursor can be also obtained by dissolving or dispersing the cyclic olefin-based resin composition in a solvent to prepare a varnish, forming a film from the varnish by any method, and drying the film, and then the obtained crosslinking precursor can be subjected to a heating or the like to proceed the crosslinking reaction.

In addition, a prepreg can be obtained by impregnating a base material with the molten cyclic olefin-based resin composition or the varnish prepared from the cyclic olefin-based resin composition, and then the obtained prepreg can be subjected to a heating or the like to proceed the crosslinking reaction.

A glass transition point (Tg) of the crosslinked body according to the present embodiment is preferably equal to or higher than 80° C., more preferably equal to or higher than 90° C., still more preferably equal to or higher than 100° C., and even more preferably equal to or higher than 110° C. As a result, the heat resistance can be improved.

The upper limit of the Tg is not particularly limited, but can be, for example, equal to or lower than 300° C.

A dielectric loss tangent (Df) of the crosslinked body according to the present embodiment is preferably equal to or less than 0.00100, more preferably equal to or less than 0.00095, still more preferably equal to or less than 0.00090, even more preferably equal to or less than 0.00085, and even still more preferably equal to or less than 0.00080. As a result, the dielectric properties can be improved.

The lower limit of the Df is not particularly limited, but is, for example, equal to or more than 0.00001.

### [Film or Sheet]

The film or the sheet according to the present embodiment includes the above-described crosslinked body.

As a method of forming the film or the sheet, various known methods can be applied.

Examples thereof include a method of applying the molten cyclic olefin-based resin composition or the varnish obtained by dissolving or dispersing the cyclic olefin-based resin composition in a solvent on a support base material such as a thermoplastic resin film, and performing a heating treatment or the like to crosslink the cyclic olefin-based resin composition.

The application method is not particularly limited, and examples thereof include a coating using a spin coater, a coating using a spray coater, and a coating using a bar coater.

### [Circuit Board]

The circuit board according to the present embodiment includes an electrically insulating layer including the above-described crosslinked body, and a conductor layer provided over the electrically insulating layer.

As described above, since the cyclic olefin-based resin composition and crosslinked body according to the present embodiment have excellent dielectric properties, heat resistance, mechanical properties, and the like, they are suitably used for the circuit board.

A method for manufacturing the circuit board according to the present embodiment is not particularly limited as long as it is a generally known method, and for example, the film, the sheet, or the prepreg manufactured by the above-described method is heated and cured by a laminating press or the like to form an electrically insulating layer. Next, a conductor layer is laminated on the obtained electrically insulating layer by a known method to produce a laminate. Thereafter, it is possible to obtain a circuit board by subjecting the conductor layer in the laminate to circuit processing or the like.

It is possible to use metals such as copper, aluminum, nickel, gold, silver, stainless steel, or the like as a metal for the conductor layer. The method for forming the conductor layer include, for example, a method in which the metal is formed into a foil or the like and thermally fused onto the electrically insulating layer; a method in which a metal is formed into a foil or the like and bonded to the electrically insulating layer using an adhesive; and a method of forming a conductor layer formed of the metal on an electrically insulating layer by a method such as sputtering, vapor deposition, and plating. As a form of the circuit board, either a single-sided board or a double-sided board may be used.

### [Electronic Apparatus]

The electronic apparatus according to the present embodiment includes the above-described circuit board.

That is, the above-described circuit board can be used as an electronic apparatus by mounting an electronic component such as a semiconductor element thereon.

It is possible to produce the electronic apparatus based on known information.

The electronic apparatus according to the present embodiment include, for example, ICT infrastructure equipment such as servers, routers, supercomputers, mainframes, and workstations; antennas such as GPS antennas, antennas for radio base stations, millimeter wave antennas, and RFID antennas; communication devices such as mobile phones, smartphones, PHSs, PDAs, and tablet terminals; digital devices such as personal computers, televisions, digital cameras, digital video cameras, POS terminals, wearable terminals, and digital media players; vehicle-mounted electronic devices such as electronic control system devices, vehicle-mounted communication devices, car navigation devices, millimeter wave radars, and in-vehicle camera modules; and semiconductor testing devices, high-frequency measurement devices, and the like.

### [Prepreg]

The prepreg according to the present embodiment contains the above-described cyclic olefin-based resin composition and a sheet-shaped fiber base material.

A method for producing the prepreg according to the present embodiment is not particularly limited, and various known methods can be applied.

For example, the prepreg can be obtained by impregnating the sheet-shaped fiber base material with the molten cyclic olefin-based resin composition or the varnish prepared from the cyclic olefin-based resin composition.

The impregnation of the sheet-shaped fiber base material can be carried out, for example, by coating a predetermined amount of varnish on the sheet-like fiber base material by a known method such as spray coating, dip coating, roll coating, curtain coating, die coating, and slit coating, overlaying a protective film thereon as necessary, and carrying out pressing with a roller or the like thereon from the upper side.

In a case where the varnish is impregnated, a step of volatilizing the solvent contained in the varnish may be included. Examples thereof include a method of drying in air or in nitrogen using a batch-type blast dryer, and a method of drying by passing through a heating furnace in a continuous process.

As a fiber constituting the sheet-shaped fiber base material, it is possible to use inorganic and/or organic fibers without particular limitation, and examples thereof include organic fibers such as polyethylene terephthalate (PET) fibers, aramid fibers, ultra-high molecular polyethylene fibers, polyamide (nylon) fibers, and liquid crystal polyester fibers; and inorganic fibers such as glass fibers, carbon fibers, alumina fibers, tungsten fibers, molybdenum fibers, titanium fibers, steel fibers, boron fibers, silicon carbide fibers, and silica fibers. Among the above, organic fibers or glass fibers are preferable, and aramid fibers, liquid crystal polyester fibers, or glass fibers are more preferable. Examples of the glass fibers include E glass, NE glass, S glass, D glass, H glass, and T glass.

The impregnation of the sheet-shaped fiber base material is carried out, for example, by dipping and applying. The impregnation may be repeated a plurality of times as necessary.

These sheet-shaped fiber base materials can be used alone or in combination of two or more kinds thereof, and the amount thereof used can be appropriately selected as desired, but is, for example, in a range of 10% to 90% by mass, preferably in a range of 20% to 80% by mass and more preferably in a range of 30% to 70% by mass in the prepreg or the laminate. Within the range, the dielectric properties and mechanical strength of the obtained laminate are highly balanced, which is preferable.

A thickness of the prepreg according to the present embodiment is appropriately selected according to the use purpose, but is usually 0.001 to 10 mm, preferably 0.005 to 1 mm and more preferably 0.01 to 0.5 mm. Within the range, shaping properties at the time of lamination and the properties such as mechanical strength and toughness of the laminate obtained by curing are sufficiently exhibited, which is preferable.

The embodiments of the present invention have been described above, but these are examples of the present invention and various configurations other than the above can be adopted.

In addition, the present invention is not limited to the above-described embodiments, and modifications, improvements, and the like within the range in which the object of the present invention can be achieved are included in the present invention.

### EXAMPLES

Hereinafter, the embodiments according to the present invention will be described in detail based on Examples, but the embodiments according to the present invention are not limited to Examples.

### [Synthesis of Cyclic Olefin-Based Copolymer]

Details of raw materials used in the synthesis of the cyclic olefin-based copolymer are as follows.
Ethylene (forming the repeating unit represented by General Formula (1) by addition copolymerization)
5-Vinyl-2-norbornene (forming the repeating unit represented by General Formula (2) by addition copolymerization; manufactured by Tokyo Chemical Industry Co., Ltd.; hereinafter, referred to as “VNB”)
2-Norbornene (forming the repeating unit represented by General Formula (3) by addition copolymerization; manufactured by Tokyo Chemical Industry Co., Ltd.; hereinafter, referred to as “NB”)
Tetracyclo[4.4.0.1^{2,5}0.1^{7,10}]-3-dodecene (forming the repeating unit represented by General Formula (3) by addition copolymerization; manufactured by Mitsui Chemicals, Inc.; hereinafter, referred to as “TD”)
Toluene (manufactured by Kanto Chemical Co., Inc.)
MMAO hexane solution (manufactured by Tosoh Finechem Corporation)
Transition metal compound represented by Formula (X) (synthesized by a method described in Japanese Unexamined Patent Publication No. 2004-331965)

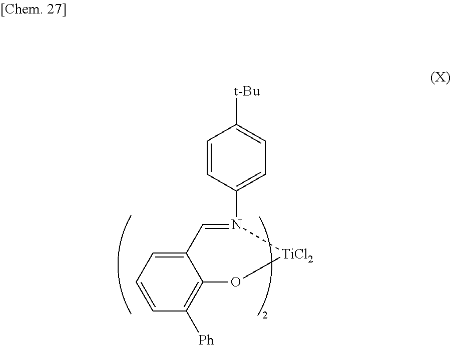

Evaluation conditions of the cyclic olefin-based copolymer are as follows.

### <Iodine Value>

The iodine value of the cyclic olefin-based copolymer was measured by a titration method conforming to JIS K 0070, using cyclohexane as a solvent.

### <Number-Average Molecular Weight (Mn)>

The number-average molecular weight (Mn) of the cyclic olefin-based copolymer was measured by GPC measurement and determined as a standard polystyrene-equivalent value. The GPC measurement was performed under the following conditions.
Apparatus: GPC HLC-8321 (manufactured by Tosoh Corporation)
Solvent: o-dichlorobenzene
Column: TSKgel GMH6-HT×2, TSKgel GMH6-HTL×2 (both manufactured by Tosoh Corporation)
Flow rate: 1.0 mL/min
Sample: 1 mg/mL o-dichlorobenzene solution
Temperature: 140° C.

Cycloolefin-based copolymers (A1) and (A2), which were the cyclic olefin-based copolymer (A), were obtained by the following procedure.

### Synthesis Example 1

450 mL of toluene, 52 mL of a toluene solution of NB adjusted to 5 mol/L, 15 mL of VNB, the MMAO hexane solution (1.5 mmol in terms of Al), and 1,490 mL of hydrogen were charged into an SUS autoclave having an internal volume of 1 L, which had been thoroughly purged with nitrogen, and then ethylene was introduced into the system until the total pressure reached 0.78 MPa.

Subsequently, 16 μmol of the above-described transition metal compound represented by Formula (X) was added thereto in a state of being dissolved in toluene, and the mixture was polymerized at 35° C. for 130 minutes to obtain a polymer solution.

The obtained polymer solution was poured into an acetone/methanol (volume ratio: 3/1) mixed solvent to which concentrated hydrochloric acid had been added in an amount of 0.1 vol % to precipitate the polymer, and the precipitate was dried under reduced pressure at 80° C. for 10 hours to obtain a cyclic olefin-based copolymer (A1).

An iodine value of the cyclic olefin-based copolymer (A1) was 42 g/100 g, and a number-average molecular weight (Mn) obtained by the GPC measurement was 7,500.

### Synthesis Example 2

450 mL of toluene, 16 mL of TD, 30 mL of VNB, the MMAO hexane solution (0.9 mmol in terms of Al), and 360 mL of hydrogen were charged into an SUS autoclave having an internal volume of 1 L, which had been thoroughly purged with nitrogen, and then ethylene was introduced into the system until the total pressure reached 0.6 MPa.

Subsequently, 28 μmol of the above-described transition metal compound represented by Formula (X) was added thereto in a state of being dissolved in toluene, and the mixture was polymerized at 35° C. for 180 minutes to obtain a polymer solution.

The obtained polymer solution was poured into an acetone/methanol (volume ratio: 3/1) mixed solvent to which concentrated hydrochloric acid had been added in an amount of 0.1 vol % to precipitate the polymer, and the precipitate was dried under reduced pressure at 80° C. for 10 hours to obtain a cyclic olefin-based copolymer (A2).

An iodine value of the cyclic olefin-based copolymer (A2) was 110 g/100 g, and a number-average molecular weight (Mn) thereof was 21,000.

A cyclic olefin-based copolymer was obtained by the following procedure. The obtained cyclic olefin copolymer had an iodine value of 140 g/100 g as shown below, and did not satisfy the requirement of the cyclic olefin-based copolymer (A) according to the present embodiment. That is, the obtained cyclic olefin copolymer corresponds to the “other cyclic olefin-based copolymers (n)” described above. Hereinafter, the cyclic olefin copolymer obtained by <Synthesis Example 3> is referred to as “other cyclic olefin copolymer (n1)”.

### Synthesis Example 3

380 mL of toluene, 26 mL of TD, 94 mL of VNB, the MMAO hexane solution (1.5 mmol in terms of Al), and 870 mL of hydrogen were charged into an SUS autoclave having an internal volume of 1 L, which had been thoroughly purged with nitrogen, and then ethylene was introduced into the system until the total pressure reached 0.78 MPa.

Subsequently, 33 μmol of the above-described transition metal compound represented by Formula (X) was added thereto in a state of being dissolved in toluene, and the mixture was polymerized at 35° C. for 180 minutes to obtain a polymer solution.

The obtained polymer solution was poured into an acetone/methanol (volume ratio: 3/1) mixed solvent to which concentrated hydrochloric acid had been added in an amount of 1 vol % to precipitate the polymer, and the precipitate was dried under reduced pressure at 80° C. for 10 hours to obtain a cyclic olefin-based copolymer.

An iodine value of the cyclic olefin-based copolymer was 140 g/100 g, and a number-average molecular weight (Mn) thereof was 11,900.

### [Preparation of Varnish]

Components shown in Table 1 were dissolved in toluene to prepare a varnish.

Details of each component used for preparing the varnish are as follows.

<Other Cyclic Olefin-Based Copolymers (n)>
Other cyclic olefin-based copolymer (n1) (the cyclic olefin copolymer obtained by <Synthesis Example 3> as described above)
Other cyclic olefin-based copolymer (n2) (a copolymer of ethylene and TD, synthesized by a method described in Examples of International Publication No. WO2008/068897; corresponding to the copolymer (n-i) of ethylene or an α-olefin with a cyclic olefin; the copolymer does not include a carbon-carbon double bond (vinyl group))

### <Radical Initiator>

Azo compound (B1) (2,2′-azobis(2,4,4-trimethylpentane), azo compound represented by the following formula; manufactured by FUJIFILM Wako Pure Chemical Corporation, product name: VR-110)

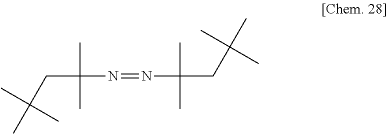 [SMILES: CC(C)(C)CC(C)(C)N=NC(C)(C)CC(C)(C)C]

Other azo compound (1) (2,2′-azobis(N-butyl-2-methylpropionamide), azo compound represented by the following formula; manufactured by FUJIFILM Wako Pure Chemical Corporation, product name: VAm-110)

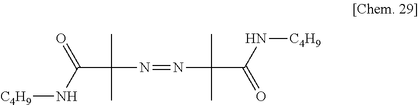

Peroxide (1) (dicumyl peroxide; manufactured by NOF CORPORATION, product name: PERCUMYL D)

### <Antioxidant>

Hindered phenol compound (C1) (hindered phenol compound represented by the following formula; manufactured by BASF, product name: Irganox 1010)

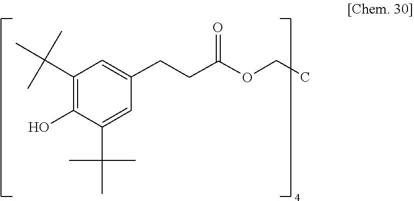

Hindered phenol compound (C2) (hindered phenol compound represented by the following formula; manufactured by BASF, product name: Irganox 1076)

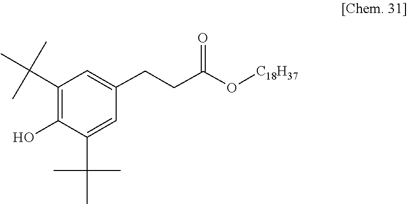

Hindered phenol compound (C3) (hindered phenol compound represented by the following formula; manufactured by BASF, product name: Irganox 1330)

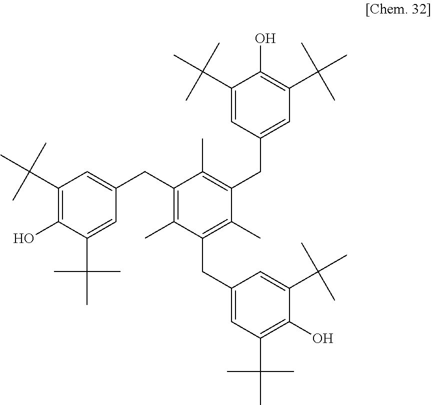 [SMILES: Cc1c(Cc2cc(C(C)(C)C)c(O)c(C(C)(C)C)c2)c(C)c(Cc2cc(C(C)(C)C)c(O)c(C(C)(C)C)c2)c(C)c1Cc1cc(C(C)(C)C)c(O)c(C(C)(C)C)c1]

### [Production and Evaluation of Crosslinked Body]

### <Production of Crosslinked Body>

The obtained varnish was impregnated into a fibrous base material (manufactured by Asahi Kasei Corporation, #1035 type, L2 glass), and then dried at 120° C. to obtain a prepreg. In this case, a content (resin content) of components constituting a resin in the prepreg, which was obtained by a curing reaction of a resin, an initiator, and the like, was adjusted to be approximately 80%.

The obtained prepregs were laminated in two layers, and heated to 200° C. at a temperature rising rate of 4° C./min, and vacuum-press molded at 200° C. for 120 minutes under a pressure of 3 MPa, thereby obtaining a crosslinked body having a thickness of 150 μm.

### <Measurement of Dielectric Loss Tangent (Df)>

The obtained crosslinked body was evaluated for dielectric loss tangent (Df) at 10 GHz by a cylindrical cavity resonator method. The results are shown in Table 1.

### <Measurement of Glass Transition Point Temperature (Tg)>

The obtained crosslinked body was subjected to a measurement of temperature dispersion of solid viscoelasticity, and a peak temperature of tan 5 was defined as a glass transition point temperature (Tg). The measurement was performed under the following conditions. The results are shown in Table 1.
Device: DMS6100 manufactured by Seiko Instruments Inc.
Deformation mode: tensile
Temperature rise rate: 5° C./min
Frequency: 10 Hz
Environment: in the air

TABLE 1

| | | | Example | Example | Example | Example | Example | Example | Comparative |
|---|---|---|---|---|---|---|---|---|---|
| | | Unit | 1 | 2 | 3 | 4 | 5 | 6 | Example 1 |
| Cyclic | Cyclic olefin-based | Part by | 100 | 0 | 0 | 100 | 100 | 100 | 100 |
| olefin- | copolymer (A1): iodine | mass | | | | | | | |
| based | value 42 g/100 g, Mn 7,500 | | | | | | | | |
| copolymer | Cyclic olefin-based | Part by | 0 | 100 | 70 | 0 | 0 | 0 | 0 |
| | copolymer (A2): iodine | mass | | | | | | | |
| | value 110 g/100 g, Mn 21,000 | | | | | | | | |
| | Other cyclic olefin-based | Part by | 0 | 0 | 0 | 0 | 0 | 0 | 0 |
| | copolymer (n1): iodine | mass | | | | | | | |
| | value 140 g/100 g, Mn 11,900 | | | | | | | | |
| | Other cyclic olefin-based | Part by | 0 | 0 | 30 | 0 | 0 | 0 | 0 |
| | copolymer (n2): not | mass | | | | | | | |
| | containing vinyl group | | | | | | | | |
| Radical | Azo compound | Part by | 2.1 | 2.1 | 2.1 | 2.1 | 2.1 | 4.0 | 0 |
| initiator | (B1): VR-110 | mass | | | | | | | |
| | Other azo compound | Part by | 0 | 0 | 0 | 0 | 0 | 0 | 2.1 |
| | (1): Vam-110 | mass | | | | | | | |
| | Peroxide (1): | Part by | 0 | 0 | 0 | 0 | 0 | 0 | 0 |
| | PERCUMYL D | mass | | | | | | | |
| Antioxidant | Hindered phenol | Part by | 0.06 | 0.06 | 0.06 | 0 | 0 | 0.06 | 0.06 |
| | compound (C1): | mass | | | | | | | |
| | Irganox 1010 | | | | | | | | |
| | Hindered phenol | Part by | 0 | 0 | 0 | 0.06 | 0 | 0 | 0 |
| | compound (C2): | mass | | | | | | | |
| | Irganox 1076 | | | | | | | | |
| | Hindered phenol | Part by | 0 | 0 | 0 | 0 | 0.06 | 0 | 0 |
| | compound (C3): | mass | | | | | | | |
| | Irganox 1330 | | | | | | | | |
| Evaluation | Dielectric loss | — | 0.00070 | 0.00095 | 0.00096 | 0.00085 | 0.00091 | 0.00066 | 0.00154 |
| result | tangent Df | | | | | | | | |
| | Glass transition | ° C. | 107 | 112 | 110 | 91 | 107 | 107 | 103 |
| | point temperature | | | | | | | | |
| | Tg | | | | | | | | |

| | | | Comparative | Comparative | Comparative | Comparative | Comparative |
|---|---|---|---|---|---|---|---|
| | | Unit | Example 2 | Example 3 | Example 4 | Example 5 | Example 6 |
| Cyclic | Cyclic olefin-based | Part by | 0 | 0 | 100 | 100 | 0 |
| olefin- | copolymer (A1): iodine | mass | | | | | |
| based | value 42 g/100 g, Mn 7,500 | | | | | | |
| copolymer | Cyclic olefin-based | Part by | 0 | 0 | 0 | 0 | 70 |
| | copolymer (A2): iodine | mass | | | | | |
| | value 110 g/100 g, Mn 21,000 | | | | | | |
| | Other cyclic olefin-based | Part by | 100 | 0 | 0 | 0 | 0 |
| | copolymer (n1): iodine | mass | | | | | |
| | value 140 g/100 g, Mn 11,900 | | | | | | |
| | Other cyclic olefin-based | Part by | 0 | 100 | 0 | 0 | 30 |
| | copolymer (n2): not | mass | | | | | |
| | containing vinyl group | | | | | | |
| Radical | Azo compound | Part by | 2.1 | 2.1 | 0 | 2.1 | 0 |
| initiator | (B1): VR-110 | mass | | | | | |
| | Other azo compound | Part by | 0 | 0 | 0 | 0 | 0 |
| | (1): Vam-110 | mass | | | | | |
| | Peroxide (1): | Part by | 0 | 0 | 0 | 0 | 2.1 |
| | PERCUMYL D | mass | | | | | |
| Antioxidant | Hindered phenol | Part by | 0.06 | 0.06 | 0.06 | 0 | 0.06 |
| | compound (C1): | mass | | | | | |
| | Irganox 1010 | | | | | | |
| | Hindered phenol | Part by | 0 | 0 | 0 | 0 | 0 |
| | compound (C2): | mass | | | | | |
| | Irganox 1076 | | | | | | |
| | Hindered phenol | Part by | 0 | 0 | 0 | 0 | 0 |
| | compound (C3): | mass | | | | | |
| | Irganox 1330 | | | | | | |
| Evaluation | Dielectric loss | — | 0.00137 | 0.00082 | 0.00118 | 0.00262 | 0.00147 |
| result | tangent Df | | | | | | |
| | Glass transition | ° C. | 123 | 80 | 89 | 107 | 86/143 |
| | point temperature | | | | | | |
| | Tg | | | | | | |

In Examples, both high Tg and low dielectric loss tangent were achieved. From the result, it was found that, with the cyclic olefin-based resin composition according to the present embodiment, it was possible to provide a prepreg in which both the heat resistance was improved and the dielectric loss tangent was reduced.

From a comparison with Comparative Examples, it was found that, in a case where an azo compound containing a heteroatom other than the azo group (Comparative Example 1) or in a case where the iodine value of the cyclic olefin-based copolymer exceeded the predetermined range (Comparative Example 2), the dielectric loss tangent was increased. In addition, it was found that, in a case where the cyclic olefin-based copolymer not including the carbon-carbon double bond was used (Comparative Example 3), Tg was lowered.

Priority is claimed on Japanese Patent Application No. 2022-056329, filed Mar. 30, 2022, the disclosure of which is incorporated herein by reference.

1. A cyclic olefin-based resin composition comprising:
a cyclic olefin-based copolymer (A);
an azo compound (B) which has an azo group in a molecule and includes no heteroatom other than a nitrogen atom constituting the azo group; and
a hindered phenol compound (C),
wherein the cyclic olefin-based copolymer (A) includes a repeating unit derived from one or more olefins represented by General Formula (1), a repeating unit derived from one or more cyclic non-conjugated dienes represented by General Formula (2), and a repeating unit derived from one or more cyclic olefins represented by General Formula (3),
an iodine value of the cyclic olefin-based copolymer (A) is in a range of equal to or more than 20 g/100 g and equal to or less than 120 g/100 g, and
a number-average molecular weight Mn of the cyclic olefin-based copolymer (A) is in a range of equal to or more than 3,000 and equal to or less than 30,000, 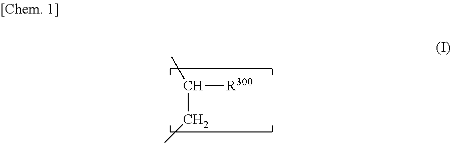
in General Formula (1), R³⁰⁰ represents a hydrogen atom or a linear or branched hydrocarbon group having 1 to 29 carbon atoms, 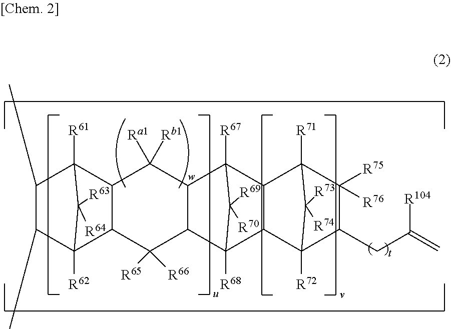
in General Formula (2), u is 0 or 1, v is 0 or a positive integer, w is 0 or 1, R⁶¹ to R⁷⁶, R^{a1}, and R^{b1} may be the same or different from each other, and are each a hydrogen atom, a halogen atom, an alkyl group having 1 to 20 carbon atoms, a halogenated alkyl group having 1 to 20 carbon atoms, a cycloalkyl group having 3 to 15 carbon atoms, or an aromatic hydrocarbon group having 6 to 20 carbon atoms, R¹⁰⁴ is a hydrogen atom or an alkyl group having 1 to 10 carbon atoms, t is a positive integer of 0 to 10, and R⁷⁵ and R⁷⁶ may be bonded to each other to form a monocyclic ring or a polycyclic ring, 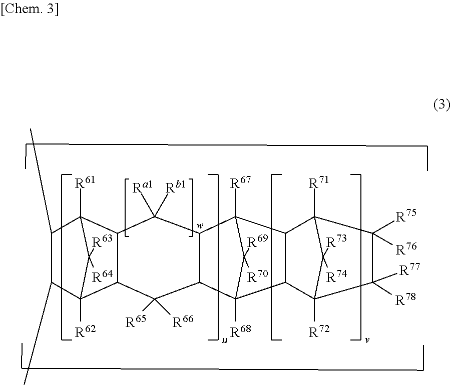
in General Formula (3), u is 0 or 1, v is 0 or a positive integer, w is 0 or 1, R⁶¹ to R⁷⁸, R^{a1}, and R^{b1} may be the same or different from each other, and are each a hydrogen atom, a halogen atom, an alkyl group having 1 to 20 carbon atoms, a halogenated alkyl group having 1 to 20 carbon atoms, a cycloalkyl group having 3 to 15 carbon atoms, or an aromatic hydrocarbon group having 6 to 20 carbon atoms, and R⁷⁵ to R⁷⁸ may be bonded to each other to form a monocyclic ring or a polycyclic ring.

2. The cyclic olefin-based resin composition according to claim 1,
wherein the cyclic olefin-based copolymer (A) includes, as the repeating unit represented by General Formula (2), a repeating unit derived from 5-vinyl-2-norbornene, and includes, as the repeating unit represented by General Formula (3), at least one of a repeating unit derived from bicyclo[2.2.1]-2-heptene or a repeating unit derived from tetracyclo[4.4.0.1^{2,5}0.1^{7,10}]-3-dodecene.

3. The cyclic olefin-based resin composition according to claim 1,
wherein the azo compound (B) includes a compound represented by General Formula (4),
[Chem. 4]
R²¹—N═N—R²² (4)
in General Formula (4), R²¹ and R²² each independently represent a hydrogen atom or an alkyl group.

4. The cyclic olefin-based resin composition according to claim 3,
wherein, in General Formula (4), the alkyl group represented by R²¹ and R²² has 1 to 8 carbon atoms.

5. The cyclic olefin-based resin composition according to claim 4,
wherein the azo compound (B) includes at least one of a compound represented by Formula (5) or a compound represented by Formula (6),

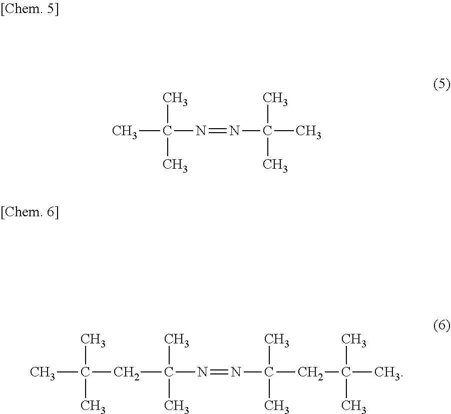

6. The cyclic olefin-based resin composition according to claim 1,
wherein the hindered phenol compound (C) has a structure represented by General Formula (7), 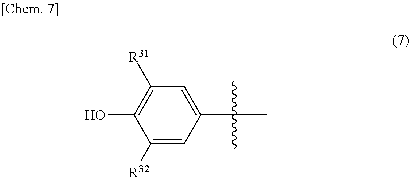
in General Formula (7), R³¹ represents an alkyl group having 1 to 4 carbon atoms, and R³² represents a hydrogen atom or an alkyl group having 1 to 4 carbon atoms.

7. The cyclic olefin-based resin composition according to claim 6,
wherein a compound in which R³¹ and R³² in General Formula (7) are both a t-butyl group is included.

8. The cyclic olefin-based resin composition according to claim 7,
wherein the hindered phenol compound (C) includes a compound represented by General Formula (8), 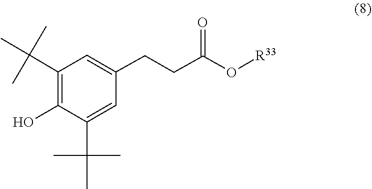
in General Formula (8), R³³ represents an organic group.

9. The cyclic olefin-based resin composition according to claim 1, further comprising:
an inorganic filler.

10. The cyclic olefin-based resin composition according to claim 1, further comprising:
a flame retardant.

11. A varnish comprising:
the cyclic olefin-based resin composition according to claim 1; and
a solvent.

12. A crosslinked body of the cyclic olefin-based resin composition according to claim 1.

13. A film or a sheet, comprising:
the crosslinked body according to claim 12.

14. A circuit board comprising:
an electrically insulating layer including the crosslinked body according to claim 12; and
a conductor layer provided over the electrically insulating layer.

15. An electronic apparatus comprising:
the circuit board according to claim 14.

16. A prepreg comprising:
the cyclic olefin-based resin composition according to claim 1; and
a sheet-shaped fiber base material.
